(19) United States
(12) Patent Application Publication
(10) Pub. No.: US 2024/0282490 A1
(43) Pub. Date: Aug. 22, 2024

(54) SOFT MAGNETIC NANOWIRE, COATING MATERIAL COMPRISING SAME, AND LAMINATED BODY OBTAINED BY APPLYING COATING MATERIAL

(71) Applicant: UNITIKA LTD., Osaka-shi, Osaka (JP)

(72) Inventors: Hirotaka TAKEDA, Uji-shi, Kyoto (JP); Masumi MIYO, Uji-shi, Kyoto (JP); Naho TAKAHASHI, Uji-shi, Kyoto (JP)

(73) Assignee: UNITIKA LTD., Osaka-shi, Osaka (JP)

(21) Appl. No.: 18/684,940

(22) PCT Filed: Aug. 24, 2022
(86) PCT No.: PCT/JP2022/031782

§ 371 Date: Feb. 20, 2024

(30) Foreign Application Priority Data
Aug. 25, 2021 (JP) 2021-137421
Aug. 25, 2021 (JP) 2021-137422
Dec. 7, 2021 (JP) 2021-198605
Dec. 7, 2021 (JP) 2021-198606
Mar. 31, 2022 (JP) 2022-059533
Mar. 31, 2022 (JP) 2022-059546
May 26, 2022 (JP) 2022-086287

(51) Int. Cl. H01F 1/147; C22C 38/00; H05K 9/00

(52) U.S. Cl. CPC H01F 1/147; C22C 38/002; H05K 9/009

(57) ABSTRACT

The present invention provides a soft magnetic nanowire having a sufficiently high saturation magnetization, a sufficiently high relative magnetic permeability and a sufficiently low coercivity force. The present invention relates to a soft magnetic nanowire, comprising an iron and a boron and having an average length of 5 μm or more and an iron/boron molar ratio in the nanowire of less than 5, wherein the iron/boron molar ratio is measured by a SEM-EDS method.

### TECHNICAL FIELD

The present invention relates to a soft magnetic nanowire, a coating material comprising the same, and a laminate body obtained by applying the coating material.

### BACKGROUND ART

Soft magnetic materials are widely used in various applications such as motor cores, electromagnetic valves, various sensors, magnetic field shields, and electromagnetic wave absorbers. In general, to obtain good performance in each application, it is preferable that the soft magnetic material has a high magnetic permeability, a high saturation magnetization, and a low coercivity. As these characteristic values are better, excellent performance is exhibited in each application.

In particular, iron is a soft magnetic material having high saturation magnetization, and is applied to sensors, core materials, magnetic field shields, and the like. Further, a material having high anisotropy among iron materials is expected as a soft magnetic material because it has a low demagnetizing field and a low percolation threshold.

By imparting anisotropy to a soft magnetic material, the demagnetizing field is suppressed, and the magnetic permeability is increased. Thus, it is known that the soft magnetic nanowires of Patent Document 1, Non-patent Document 1, and the like are materials having excellent magnetic permeability as compared with soft magnetic particles.

As soft magnetic materials having anisotropy, for example, Non-patent Documents 2 and 3 disclose nanowires containing iron and boron.

On the other hand, in recent years, use of high-frequency electromagnetic waves in a quasi-millimeter wave or millimeter wave region has rapidly progressed in the Fifth Generation Mobile Communication System and advanced driver-assistance systems. When a high-frequency signal is transmitted and received by an antenna, it is necessary to shorten a circuit length from the antenna to a radio frequency integrated circuit (RFIC) or a power supply unit to suppress a transmission loss and a delay of the signal. Thus, the antenna operating at millimeter waves is mainly packaged as an AiP (antenna in package).

Due to the miniaturization of the AiP, units are densely integrated, and thus it is necessary to prevent deterioration in characteristics due to noise generated by each unit. Currently, an electromagnetic wave shield is applied to each unit, but it is necessary to design in consideration of an influence of reflection noise, leakage noise, and a loop current generated in the electromagnetic wave shield, and the design and process become very complicated and difficult.

To eliminate reflection noise and a loop current, use of an electromagnetic wave absorber is considered (for example, Patent Documents 1 to 3).

### PRIOR ART DOCUMENTS

### Patent Documents

Patent Document 1: WO 2021/107136 A
Patent Document 2: JP-A-2001-077584
Patent Document 3: JP-A-2017-165996

### Non-Patent Documents

Non-patent Document 1: Advanced Powder Technology (2016), 27, p704-710.
Non-patent Document 2: Journal of Applied Physics (2011), 109, 07B527 Non-patent Document 3: J. Chin. Chem. Soc. 2012, 59, “Synthesis and Charact

### SUMMARY OF THE INVENTION

### Problems to be Solved by the Invention

However, the nanowire of Patent Document 1 has high coercivity, and its performance is insufficient as a soft magnetic material. The nanowires of Non-patent Documents 1 to 3 have relatively short lengths and poor anisotropy, and thus their performance (in particular, relative magnetic permeability) is insufficient as soft magnetic materials.

A current electromagnetic wave absorber as in Patent Document 2 has a narrow absorption band and requires a thickness of several mm, and thus it is not suitable for use in AiP that is becoming smaller in size for the purpose of shortening the circuit length. Patent Document 3 discloses an electromagnetic wave absorber using a nanowire. However, the performance of the electromagnetic wave absorber of Patent Document 3 is insufficient, and the absorber has a problem particularly in thickness reduction.

To reduce the thickness, it is conceivable to improve the saturation magnetization and relative magnetic permeability of the nanowire to be used, and it is conceivable to increase the content of iron in the nanowire. However, in the conventional nanowire, the content of iron is limited to 65 mass % as described in Examples of Patent Document 1, and it is not possible to set the content of iron to more than 65 mass % by a typical method. Thus, conventionally, an electromagnetic wave absorber having excellent electromagnetic wave absorption cannot be obtained by using a nanowire.

An object of the present invention (in particular, the invention according to the first and second embodiments described later) is to provide a soft magnetic nanowire having a sufficiently higher saturation magnetization and relative magnetic permeability and a sufficiently lower coercivity.

An object of the present invention (in particular, the invention according to the third embodiment described later) is to solve the above problems, and is to provide an electromagnetic wave absorber having more sufficiently excellent electromagnetic wave absorption in at least one of a band of 26.5 to 40 GHz used for 5G wireless communication or a band of 74 to 81 GHz used for a millimeter wave radar (usually, either one of the above bands) even with a small thickness.

### Solutions to the Problems

As a result of intensive studies, the inventors of the present invention have found that the above object is achieved by reduction reaction of a solution containing an iron salt (and a cobalt salt and/or a nickel salt as necessary) using a reducing agent containing boron to set the average length to 5 μm or more, and have reached the present invention.

That is, the gist of the present invention is as follows.
<1> A soft magnetic nanowire, comprising an iron and a boron and having an average length of 5 μm or more and an iron/boron molar ratio in the nanowire of less than 5, wherein
the iron/boron molar ratio is measured by a SEM-EDS method.
<2> The soft magnetic nanowire according to <1>, wherein
a content of iron is 15 mass % or more with respect to a total content of iron, cobalt, nickel, boron, and silicon, and
a content of boron is 0.1 to 20 mass % with respect to the total content of iron, cobalt, nickel, boron, and silicon.
<3> The soft magnetic nanowire according to <1> or <2>, wherein
a content of each of cobalt and nickel is 0.1 mass % or less with respect to an entire amount of the nanowire,
a content of iron in the nanowire is 70 mass % or more with respect to the entire amount of the nanowire,
a content of boron in the nanowire is 3.5 mass % or more with respect to the entire amount of the nanowire, and
a content of the elements other than iron and boron in the nanowire is 25 mass % or less with respect to the entire amount of the nanowire.
<4> The soft magnetic nanowire according to <3>, wherein the content of iron in the nanowire is 85 mass % or more with respect to the entire amount of the nanowire.
<5> The soft magnetic nanowire according to <4>, wherein
the content of boron in the nanowire is 3.5 mass % or more with respect to the entire amount of the nanowire, and
the content of the elements other than iron and boron in the nanowire is 15 mass % or less with respect to the entire amount of the nanowire.
<6> The soft magnetic nanowire according to <3>, wherein
the content of iron in the nanowire is 89 mass % or more with respect to the entire amount of the nanowire, and
the content of boron in the nanowire is 4 mass % or more with respect to the entire amount of the nanowire.
<7> The soft magnetic nanowire according to <6>, wherein the content of the elements other than iron and boron in the nanowire is 8 mass % or less with respect to the entire amount of the nanowire.
<8> The soft magnetic nanowire according to <1> or <2>, wherein a total content of cobalt and nickel is 1 to 60 mass % with respect to a total content of iron, cobalt, nickel, boron, and silicon.
<9> The soft magnetic nanowire according to <8>, wherein the soft magnetic nanowire satisfies at least one of Condition (P1) or (P2) shown below:
Condition (P1): a content of iron is 60 mass % or more with respect to the total content of iron, cobalt, nickel, boron, and silicon; or
Condition (P2): a total content of iron and cobalt is 84 mass % or more with respect to the total content of iron, cobalt, nickel, boron, and silicon.
<10> The soft magnetic nanowire according to <8>, wherein the soft magnetic nanowire satisfies at least one of Condition (Q1) or (Q2) shown below:
Condition (Q1): a content of iron is 73.5 mass % or more with respect to the total content of iron, cobalt, nickel, boron, and silicon; or
Condition (Q2): a total content of iron and cobalt is 84 to 90 mass % with respect to the total content of iron, cobalt, nickel, boron, and silicon.
<11> The soft magnetic nanowire according to any one of <8> to <10>, wherein
the soft magnetic nanowire further comprises silicon, and
a content of silicon is 0.1 to 1 mass % with respect to the total content of iron, cobalt, nickel, boron, and silicon.
<12> The soft magnetic nanowire according to any one of <1> to <11>, wherein the soft magnetic nanowire has:
a saturation magnetization measured using a vibrating-sample magnetometer of 40 emu/g or more;
a coercivity measured using a vibrating-sample magnetometer of less than 500 Oe; and
a relative magnetic permeability measured using a vibrating-sample magnetometer of 5 or more.
<13> A method for producing the soft magnetic nanowire according to any one of <1> to <12>, wherein the method comprises performing, in a reaction solvent, a liquid phase reduction reaction in a magnetic field using metal ions including an iron ion as raw materials and a reducing agent containing a boron atom.
<14> The method for producing the soft magnetic nanowire according to <13>, wherein the metal ions further include a cobalt ion and/or a nickel ion.
<15> A coating material comprising the soft magnetic nanowire according to any one of <1> to <12>.
<16> A laminated body comprising a coating film formed by applying the coating material according to <15> onto a substrate.
<17> A molded body comprising the soft magnetic nanowire according to any one of <1> to <12>.
<18> A sheet comprising the soft magnetic nanowire according to any one of <1> to <12>.
<19> An electromagnetic wave shielding material comprising the soft magnetic nanowire according to any one of <1> to <12>.
<20> An electromagnetic wave absorber comprising a nanowire (A) and a binder (B), wherein
the nanowire (A) contains boron and iron, and a content of iron with respect to a total of iron, nickel, and boron in the nanowire (A) measured by an ICP-AES method is 65 mass % or more, and
a content of the nanowire (A) is 85 mass % or less with respect to the nanowire (A) and the binder (B).
<21> The electromagnetic wave absorber according to <20>, wherein
the content of iron with respect to the total of iron, nickel, and boron in the nanowire (A) measured by the ICP-AES method is 65 mass % or more and less than 80 mass %, and
the content of the nanowire (A) is 45 to 85 mass % with respect to a total of the nanowire (A) and the binder (B).
<22> The electromagnetic wave absorber according to <20>, wherein
the content of iron with respect to the total of iron, nickel, and boron in the nanowire (A) measured by the ICP-AES method is 80 to 95 mass %, and
the content of the nanowire (A) is 45 to 85 mass % with respect to a total of the nanowire (A) and the binder (B).
<23> The electromagnetic wave absorber according to <20>, wherein
the content of iron with respect to the total of iron, nickel, and boron in the nanowire (A) measured by the ICP-AES method is 65 mass % or more and less than 80 mass %, and
the content of the nanowire (A) is 25 mass % or more and less than 45 mass % with respect to a total of the nanowire (A) and the binder (B).
<24> The electromagnetic wave absorber according to any one of <20> to <23>, wherein the electromagnetic wave absorber has a thickness of 1 mm or less.
<25> The electromagnetic wave absorber according to any one of <20> to <24>, wherein a value of average length/average diameter of the nanowire (A) is 50 or more.
<26> The electromagnetic wave absorber according to any one of <20> to <25>, wherein the electromagnetic wave absorber is a millimeter wave absorber.
<27> The electromagnetic wave absorber according to <21>, wherein the electromagnetic wave absorber has an average value of electromagnetic wave absorption in a band of 26.5 to 40 GHz of 15 dB or more with a thickness of 100 μm.
<28> The electromagnetic wave absorber according to <22> or <23>, wherein the electromagnetic wave absorber has an average value of electromagnetic wave absorption in a band of 74 to 81 GHz of 15 dB or more with a thickness of 100 μm.
<29> An antenna unit for wireless communication comprising the electromagnetic wave absorber according to any one of <20> to <28> in a package.
<30> A sensing unit comprising the electromagnetic wave absorber according to any one of <20> to <28> in a package.

### Effects of the Invention

The present invention (in particular, the invention according to the first and second embodiments described later) can provide a soft magnetic nanowire having a more sufficiently high saturation magnetization and relative magnetic permeability and a more sufficiently low coercivity.

The soft magnetic nanowire of the present invention (in particular, the invention according to the first and second embodiments described later) can be made into a material suitable for various applications (for example, a coating material, a laminated body, a laminated body, a sheet, an electromagnetic wave shielding material, and an electromagnetic wave absorber) by processing such as mixing with a binder.

The present invention (in particular, the invention according to the third embodiment described later) can provide an electromagnetic wave absorber having more sufficiently excellent electromagnetic wave absorption in at least one of a band of 26.5 to 40 GHz used for 5G wireless communication and a band of 74 to 81 GHz used for a millimeter wave radar (usually, either one of the above bands) even with a small thickness.

The electromagnetic wave absorber of the present invention (in particular, the invention according to the third embodiment described later) can be suitably used for an antenna unit for wireless communication and a sensing unit.

### BRIEF DESCRIPTION OF THE DRAWINGS

FIG. 1 is a diagram showing magnetization curves of Examples 2-1, 2-2, 2-4, and Comparative Example 2-1.

FIG. 2 is a diagram showing a chart of a WAXD reflection method of Examples 2-1, 2-2, 2-4, and Comparative Example 2-2.

### DETAILED DESCRIPTION

The present invention includes first and second embodiments related to a soft magnetic nanowire and a third embodiment related to an electromagnetic wave absorber.

### First and Second Embodiments: Soft Magnetic Nanowire

The soft magnetic nanowires of first and second embodiments contain iron and boron.

The molar ratio of iron/boron in the soft magnetic nanowires of the first and second embodiments needs to be less than 5, and the molar ratio is preferably less than 4, and more preferably less than 3, from the viewpoint of further increasing the saturation magnetization and relative magnetic permeability and further reducing the coercivity. When the molar ratio is 5 or more, the saturation magnetization and the relative magnetic permeability decrease. The molar ratio is usually 0.1 or more, particularly 0.5 or more (preferably 1 or more).

As the molar ratio of iron/boron, a value measured by a scanning electron microscope (SEM)-EDS method is used. Specifically, as the molar ratio, an average value calculated by measuring the constituent ratio of each element by the EDS method in any 10 fields of view by SEM is used.

The content of iron in the soft magnetic nanowires of the first and second embodiments is not particularly limited, and is usually 15 mass % or more with respect to the total content (hereinafter, may be simply referred to as “total content X”) of iron, cobalt, nickel, boron, and silicon, and is preferably 30 mass % or more from the viewpoint of high saturation magnetization. The upper limit value of the content of iron is not particularly limited, and the content of iron is usually 98 mass % or less with respect to the total content X. When the nanowire does not contain iron, the saturation magnetization is lowered, which is not preferable. A soft magnetic material can be obtained by containing iron.

The content of boron in the soft magnetic nanowires of the first and second embodiments is not particularly limited, and is usually 0.1 mass % or more (particularly 0.1 to 20 mass %) with respect to the total content X, and is preferably 2 to 15 mass % and more preferably 3 to 10 mass % from the viewpoint of further increasing the saturation magnetization and relative magnetic permeability and further reducing the coercivity. Containing boron in the soft magnetic nanowire makes it possible to control the ratio between the crystalline part and the amorphous part of the nanowire, and to suppress an increase in coercivity even when the length of the nanowire is long. When the nanowire does not contain boron, the proportion of the amorphous part is low, and the increase in coercivity cannot be suppressed in some cases.

Originally, as the content of iron is higher, the performance as a soft magnetic material such as saturation magnetization is improved, but since iron is easily oxidized, oxygen or the like is contained in the nanowire, and the purity is reduced. However, in the present invention, the nanowire can be grown while suppressing oxidation by containing boron in the nanowire, and a nanowire having high iron purity can be produced. In addition, by containing boron in the nanowire, high purity can be maintained even when the nanowire is stored after production. When the nanowire does not contain iron, the saturation magnetization is lowered, which is not preferable. When the nanowire does not contain boron, there is a possibility that a nanowire having a predetermined average length cannot be produced.

The elements other than iron and boron contained in the soft magnetic nanowires of the first and second embodiments and the contents thereof are not particularly limited. Hereinafter, a case where the soft magnetic nanowire contains iron and boron and is substantially free from cobalt and nickel will be described as the first embodiment, and a case where the soft magnetic nanowire substantially contains cobalt and/or nickel will be described as the second embodiment.

The average length of the soft magnetic nanowires of the first and second embodiments needs to be 5 μm or more, and is preferably 8 to 40 μm, more preferably 10 to 35 μm, and still more preferably 10 to 30 μm from the viewpoint of further increasing the saturation magnetization and relative magnetic permeability and further reducing the coercivity. Containing boron as described above makes it possible to produce a nanowire having an average length of 5 μm or more. The longer the nanowire, the higher the anisotropy and the lower the demagnetizing field. When the average length of the nanowires is less than 5 μm, the saturation magnetization and relative magnetic permeability decrease.

The average diameter of the soft magnetic nanowires of the first and second embodiments is not particularly limited, and is preferably 20 to 300 nm, more preferably 50 to 200 nm, and still more preferably 50 to 150 nm from the viewpoint of further increasing the saturation magnetization and relative magnetic permeability and further reducing the coercivity. The average diameter can be controlled by reaction conditions, and can be appropriately selected according to the application. A thinner nanowire has an increased aspect ratio and reduced demagnetizing field. The aspect ratio of the soft magnetic nanowires of the first and second embodiments is not particularly limited, and may be, for example, 20 to 500, and is preferably 40 to 300, and more preferably 50 to 200 from the viewpoint of further increasing the saturation magnetization and relative magnetic permeability and further reducing the coercivity.

In the present specification, as the average length and the average diameter of the nanowire, an average value of any 100 points based on photographing by a scanning electron microscope (SEM) is used.

The saturation magnetization of the soft magnetic nanowires of the first and second embodiments is preferably 40 emu/g or more, more preferably 60 emu/g or more, still more preferably 70 emu/g or more, and particularly preferably 150 emu/g or more. When the saturation magnetization is less than 40 emu/g, the performance is insufficient and the nanowire is difficult to handle as a soft magnetic material. The saturation magnetization is usually 300 emu/g or less, particularly 200 emu/g or less.

In the soft magnetic nanowires of the first and second embodiments, the value obtained by dividing the saturation magnetization by the purity of iron is preferably 40 emu/g or more, more preferably 60 emu/g or more, still more preferably 70 emu/g or more, and particularly preferably 150 emu/g or more. The purity of iron is a value based on the content of iron in the nanowire, and is a value when the total mass of the nanowire is “1”.

The relative magnetic permeability of the soft magnetic nanowires of the first and second embodiments is preferably 5 or more, more preferably 10 or more, still more preferably 40 or more, and sufficiently preferably 100 or more. When the relative magnetic permeability is less than 5, the performance is insufficient and the nanowire is difficult to handle as a soft magnetic material. The relative magnetic permeability is usually 300 or less, and particularly 200 or less.

The coercivity of the soft magnetic nanowires of the first and second embodiments is preferably less than 500 Oe, more preferably less than 400 Oe, and still more preferably less than 200 Oe. When the coercivity is 500 Oe or more, the nanowire is hard to respond to the magnetic field, and is difficult to handle as a soft magnetic material. In general, the higher the anisotropy, the higher the coercivity. However, containing boron makes it possible to suppress an increase in coercivity. The coercivity is usually 50 Oe or more, particularly 100 Oe or more.

In the present specification, as the saturation magnetization, relative magnetic permeability, and coercivity, an average value of values (two measured values) obtained by a vibrating-sample magnetometer (VSM) at 25° C. is used.

The soft magnetic nanowires of the first and second embodiments have anisotropy. Anisotropy means that the aspect ratio of the nanowire is sufficiently large. The soft magnetic nanowires of the first and second embodiments preferably have a more sufficiently large aspect ratio as described above.

### First Embodiment

The soft magnetic nanowire of the first embodiment contains iron and boron and is substantially free from cobalt and nickel.

The content of iron in the soft magnetic nanowire of the first embodiment is preferably 70 mass % or more, more preferably 85 mass % or more, still more preferably 88 mass % or more, sufficiently preferably 89 mass % or more, more sufficiently preferably 90 mass % or more, particularly preferably 93 mass % or more, and most preferably 95 mass % or more, with respect to the entire amount of the nanowire, from the viewpoint of further increasing the saturation magnetization and the relative magnetic permeability and further reducing the coercivity. The content of iron is usually 98 mass % or less, particularly 95 mass % or less with respect to the entire amount of the nanowire.

The content of boron in the soft magnetic nanowire of the first embodiment is preferably 3.5 mass % or more, more preferably 4 mass % or more, sufficiently preferably 4.85 mass % or more, and more sufficiently preferably 5 mass % or more with respect to the entire amount of the nanowire, from the viewpoint of further increasing the saturation magnetization and relative magnetic permeability and further reducing the coercivity. The content of boron is usually 15 mass % or less, and particularly 8 mass % or less.

In the first embodiment, the content of each element of iron and boron may be represented by a value (mass %) with respect to the entire amount of the nanowire. As the content of each element, a value measured by subjecting a solution in which the nanowire is dissolved to a multi-element simultaneous analysis method and a calibration curve method both based on an ICP-AES method is used.

The content of elements other than iron and boron in the soft magnetic nanowire of the first embodiment is not particularly limited, and is preferably 25 mass % or less, more preferably 15 mass % or less, still more preferably 8 mass % or less, sufficiently preferably 7 mass % or less, more sufficiently preferably 6 mass % or less, still more sufficiently preferably 5 mass % or less, yet still more sufficiently preferably 3 mass % or less, particularly preferably less than 1 mass %, and most preferably 0.1 mass % or less with respect to the entire amount of the nanowire, from the viewpoint of further increasing the saturation magnetization and relative magnetic permeability and further reducing the coercivity. The content of elements other than iron and boron may be less than a detection limit value (for example, 0.1 mass %).

The elements other than iron and boron are elements that are neither iron nor boron contained in the soft magnetic nanowire of the first embodiment. Specific examples of the elements other than iron and boron include, for example, oxygen, carbon, and silicon.

In the first embodiment, the content of elements other than iron and boron is the total content of these elements, and is represented by a value (mass %) with respect to the entire amount of the nanowire. As the content of the elements, a value measured by subjecting a solution in which the nanowire is dissolved to a multi-element simultaneous analysis method and a calibration curve method both based on an ICP-AES method is used. Specifically, a value calculated by subtracting the contents of iron and boron measured by a calibration curve method based on an ICP-AES method from the entire amount of the nanowire is used.

In the soft magnetic nanowire of the first embodiment, the content of each of cobalt and nickel is usually 0.1 mass % or less, and particularly 0 mass % with respect to the entire amount of the nanowire. The content of each of cobalt and nickel being 0 mass % means that the soft magnetic nanowire of the first embodiment is substantially free from cobalt and nickel, specifically, the content of each of cobalt and nickel is less than a detection limit value (for example, less than 0.1 mass %) by a measurement method based on an ICP-AES method.

The total content (that is, the “total content X”) of iron, cobalt, nickel, boron, and silicon in the soft magnetic nanowire of the first embodiment is preferably 75 mass % or more, more preferably 80 mass % or more, still more preferably 85 mass % or more, sufficiently preferably 95 mass % or more, and more sufficiently preferably 98 mass % or more with respect to the entire amount of the nanowire, from the viewpoint of further increasing the saturation magnetization and relative magnetic permeability and further reducing the coercivity. The proportion of the total content X to the entire amount of the nanowires is usually 100 mass % or less.

In the present specification, the proportion (mass %) of the total content (that is, the “total content X”) of iron, cobalt, nickel, boron, and silicon to the entire amount of the nanowire is a value measured by a calibration curve method based on an ICP-AES method.

From the viewpoint of further reducing the coercivity while maintaining good saturation magnetization and relative magnetic permeability, the soft magnetic nanowire of the first embodiment preferably contains silicon in a small amount, and more preferably does not contain silicon. The content of silicon in the soft magnetic nanowire of the first embodiment is usually 0 to 1 mass %, preferably 0 to 0.5 mass %, more preferably 0 mass % or more and less than 0.1 mass %, and still more preferably 0 mass % with respect to the total content X. In the first embodiment, when the soft magnetic nanowire does not contain silicon, the effect of boron can be assisted and the increase in coercivity can be more sufficiently suppressed. The content of silicon being 0 mass % means that the soft magnetic nanowire is substantially free from silicon, specifically, the content of silicon is less than a detection limit value (for example, less than 0.1 mass %) by a measurement method based on an ICP-AES method.

### Second Embodiment

The soft magnetic nanowire of the second embodiment contains iron, cobalt and/or nickel, and boron.

The content of iron in the soft magnetic nanowire of the second embodiment is preferably 40 mass % with respect to the total content X because high saturation magnetization can be obtained. In the second embodiment, the content of iron is preferably 50 mass % or more, more preferably 60 mass % or more, still more preferably 70 mass % or more, sufficiently preferably 73.5 mass % or more, and more sufficiently preferably 80 mass % or more with respect to the total content X from the viewpoint of further increasing the saturation magnetization and relative magnetic permeability and further reducing the coercivity. The upper limit value of the content of iron is not particularly limited, and the content of iron is usually 98 mass % or less with respect to the total content X.

The soft magnetic nanowire of the second embodiment contains at least one of cobalt or nickel. Specifically, the soft magnetic nanowire of the second embodiment may contain one of cobalt or nickel, or contain both of cobalt and nickel. The total content of cobalt and nickel is not particularly limited, and is preferably 1 to 60 mass %, more preferably 3 to 55 mass %, more preferably 5 to 50 mass %, still more preferably 5 to 30 mass %, and sufficiently preferably 5 to 25 mass % with respect to the total content X, from the viewpoint of further increasing the saturation magnetization and relative magnetic permeability and further reducing the coercivity.

The content of cobalt is usually, preferably 60 mass % or less (particularly 0 to 60 mass %) with respect to the total content X, and is preferably 50 mass % or less (particularly 0 to 50 mass %), more preferably 40 mass % or less (particularly 0 to 40 mass %), and still more preferably 0 mass % from the viewpoint of further increasing the saturation magnetization and relative magnetic permeability and further reducing the coercivity. The content of cobalt being 0 mass % means that the soft magnetic nanowire of the second embodiment does not contain cobalt, specifically, the content of cobalt is less than a detection limit value (for example, less than 0.1 mass %) by a measurement method based on an ICP-AES method.

The content of nickel is usually, preferably 60 mass % or less (particularly 0 to 60 mass %) with respect to the total content X, and is preferably 50 mass % or less (particularly 0 to 50 mass %), more preferably 30 mass % or less (particularly 0 to 30 mass %), and still more preferably 5 to 20 mass % from the viewpoint of further increasing the saturation magnetization and relative magnetic permeability and further reducing the coercivity. The content of nickel being 0 mass % means that the soft magnetic nanowire of the second embodiment does not contain nickel, specifically, the content of nickel is less than a detection limit value (for example, less than 0.1 mass %) by the measurement method based on the ICP-AES method.

The soft magnetic nanowire of the second embodiment contains boron in an amount of preferably 5 to 20 mass %, more preferably 5 to 15 mass %, still more preferably 5 to 10 mass %, sufficiently preferably 7 to 10 mass %, and more sufficiently preferably 7 to 9 mass % with respect to the total content X, from the viewpoint of further increasing the saturation magnetization and the relative magnetic permeability and further reducing the coercivity.

The total content of iron and cobalt in the soft magnetic nanowire of the second embodiment is not particularly limited, and is usually 15 mass % or more with respect to the total content X. The total content of iron and cobalt is preferably 30 mass % or more, more preferably 40 mass % or more, still more preferably 70 mass % or more, and sufficiently preferably 84 mass % or more with respect to the total content X, from the viewpoint of further increasing the saturation magnetization and relative magnetic permeability and further reducing the coercivity. The upper limit value of the total content of iron and cobalt is not particularly limited, and the total content of iron and cobalt is usually 98 mass % or less with respect to the total content X.

The soft magnetic nanowire of the second embodiment preferably contains silicon from the viewpoint of further reducing the coercivity while maintaining good saturation magnetization and relative magnetic permeability. When silicon is contained, silicon is contained in an amount of preferably 0.1 to 1 mass %, more preferably 0.1 to 0.5 mass % with respect to the total content X. In the second embodiment, containing silicon together with cobalt and/or nickel makes it possible to assist the effect of boron and sufficiently suppress the increase in coercivity.

The soft magnetic nanowire of the second embodiment satisfies at least one of the following condition (P1) or (P2) in a particularly preferred embodiment from the viewpoint of further increasing the saturation magnetization and relative magnetic permeability and further reducing the coercivity. Specifically, a particularly preferred soft magnetic nanowire of the second embodiment may satisfy one of the condition (P1) or (P2), or satisfy both of the conditions (P1) and (P2).

Condition (P1): The content of iron is 60 mass % or more with respect to the total content X. Under this condition, the upper limit value of the content of iron is not particularly limited, and the content of iron is usually 98 mass % or less with respect to the total content X.

Condition (P2): The total content of iron and cobalt is 84 mass % or more with respect to the total content X. Under this condition, the upper limit value of the total content of iron and cobalt is not particularly limited, and the total content of iron and cobalt is usually 98 mass % or less with respect to the total content X.

The soft magnetic nanowire of the second embodiment satisfies at least one of the following condition (Q1) or (Q2) in a particularly more preferred embodiment from the viewpoint of further increasing the saturation magnetization and relative magnetic permeability and further reducing the coercivity. Specifically, a particularly more preferred soft magnetic nanowire of the second embodiment may satisfy one of the condition (Q1) or (Q2), or satisfy both of the conditions (Q1) and (Q2). In the particularly more preferred embodiment, the soft magnetic nanowire of the second embodiment may usually satisfy only the condition (Q1) of the conditions (Q1) or (Q2).

Condition (Q1): The content of iron is 73.5 mass % or more with respect to the total content X. Under this condition, the upper limit value of the content of iron is not particularly limited, and the content of iron is usually 98 mass % or less with respect to the total content X.

Condition (Q2): The total content of iron and cobalt is 84 to 90 mass % with respect to the total content X.

In the second embodiment, the content of each element of iron, cobalt, nickel, boron, and silicon may be represented by a value (mass %) with respect to the total content (that is, “total content X”) of these elements. Thus, the content of each element may also be referred to as a constituent ratio of the nanowire. As the content of each element, a value measured by subjecting a solution in which the nanowire is dissolved to a multi-element simultaneous analysis method and a calibration curve method both based on an ICP-AES method is used.

The total content (that is, the “total content X”) of iron, cobalt, nickel, boron, and silicon in the soft magnetic nanowire of the second embodiment is preferably 60 mass % or more, more preferably 65 mass % or more, still more preferably 70 mass % or more, and sufficiently preferably 75 mass % or more with respect to the entire amount of the nanowire. The upper limit value of the proportion of the total content X to the entire amount of the nanowire is not particularly limited, and the proportion is usually 98 mass % or less. The nanowire of the second embodiment may contain, as elements other than iron, cobalt, nickel, boron, and silicon, elements (for example, oxygen and/or carbon) that are difficult to quantify by ICP-AES because liquefying as pretreatment is difficult to be performed, which include rare gas elements, hydrogen, carbon, oxygen, nitrogen and the like.

### First and Second Embodiments: Method for Producing Soft Magnetic Nanowire

The method for producing the nanowire according to the first and second embodiments is not particularly limited, and examples thereof include a method in which a liquid phase reduction reaction of metal ions as a raw material in a reaction solvent is performed in a magnetic field using a reducing agent containing a boron atom. The metal ions include iron ions (the first and second embodiments), and further include cobalt ions and/or nickel ions as necessary (the second embodiment).

When metal ions are reduced in a magnetic field, it is preferable to supply metal ions by dissolving a metal salt in a reaction solvent. The form of the metal salt is not particularly limited as long as it can be dissolved in the reaction solvent to be used and metal ions can be supplied in a reducible state. Examples of the metal salt include chlorides, sulfates, nitrates, and acetates of iron, cobalt, and nickel. These salts may be hydrated or anhydrous. The valence of the metal ion is not particularly limited. For example, in the case of an iron ion, the iron ion may be either an iron (II) ion or an iron (III) ion.

The type and concentration of metal ions may be such that the resulting nanowire has a desired constituent ratio. Adjusting the concentration of each metal ion while selecting the type of metal ions makes it possible to control the composition and constituent ratio of the nanowire. The concentration of the metal ions is preferably 10 to 1000 mmol/L in total of iron, cobalt, and nickel, more preferably 30 to 300 mmol/L, and still more preferably 50 to 200 mmol/L because a nanowire is easily formed and the yield tends to improve.

In the reaction solution containing metal ions, the amount of dissolved oxygen before the start of the reaction is preferably controlled to 0.5 to 4.0 mg/L, and particularly preferably controlled to 1.0 to 3.0 mg/L. When the amount of dissolved oxygen exceeds 4.0 mg/L, the average length of the nanowire does not grow up to a length of 5 μm or more in some cases. In some cases, performing a surface treatment with a basic aqueous solution described later makes it possible to obtain a nanowire having an average length of more than 5 μm even when the amount of dissolved oxygen exceeds 4.0 mg/L. On the other hand, when the amount of dissolved oxygen is less than 0.5 mg/L, an unstable nanowire in which reionization or the like is likely to occur may be formed. The amount of dissolved oxygen can be controlled by degassing with an inert gas or using a deoxygenating agent.

In the first and second embodiments, the reducing agent needs to be a reducing agent containing a boron atom such as sodium borohydride, potassium borohydride, or dimethylamine borane, and among them, sodium borohydride is preferable. When a reducing agent containing no boron atom is used, a nanowire is not obtained in some cases. In particular, in the second embodiment, the reducing agent is preferably a reducing agent containing silicon as an impurity. The reducing agent containing silicon as an impurity is, for example, a reducing agent containing silicon in a trace amount as sodium silicate. In such a reducing agent containing silicon in a trace amount, the content of silicon is usually 0.5 mass % or less, and particularly 0.1 mass % or less.

The concentration of the reducing agent is not particularly limited, and is preferably 50 to 2000 mmol/L, more preferably 100 to 1000 mmol/L, and still more preferably 150 to 600 mmol/L. When the concentration of the reducing agent is less than 50 mmol/L, the reduction reaction does not sufficiently proceed in some cases, and when the concentration of the reducing agent exceeds 2000 mmol/L, rapid bubbling due to the progress of the reduction reaction may occur.

The reaction solvent is not particularly limited as long as the metal ions and the reducing agent can be dissolved, but water is preferable from the viewpoint of solubility, price, environmental load, and the like.

In the reduction reaction, it is preferable that one solution of the metal ion solution and the reducing agent solution is added dropwise to the other solution to form a reaction solution. Specifically, the reducing agent solution may be added dropwise to the metal ion solution, or the metal ion solution may be added dropwise to the reducing agent solution. From the viewpoint of further increasing the saturation magnetization and relative magnetic permeability and further reducing the coercivity, it is preferable to add the reducing agent solution dropwise to the metal ion solution. The concentration of the metal ions and the reducing agent described above is the concentration in the reaction solution (that is, the mixed solution of the metal ion solution and the reducing agent solution).

The reduction reaction may be performed by a batch method or a flow method.

The magnetic field applied at the time of reducing the metal ions is preferably set to have a central magnetic field of 10 to 200 mT in any of the batch method and the flow method. When the central magnetic field is less than 10 mT, it may be difficult to generate a soft magnetic nanowire. Strong magnetic fields above 200 mT are difficult to generate.

The temperature at which the reduction reaction is performed is not particularly limited, but is preferably a temperature from room temperature (for example, 25° C.) to the boiling point of the solvent, and is more preferably performed at room temperature from the viewpoint of simplicity.

The time for the reduction reaction is not particularly limited as long as a soft magnetic nanowire can be produced. When the reaction is performed by the batch method, the time for the reduction reaction is preferably 1 minute to 1 hour. When the reaction is performed by the flow method, the solution after the reaction may be taken out after a predetermined time elapses, or the solution after the reaction may be continuously taken out.

In the reduction reaction, bubbling with an inert gas such as nitrogen or argon may be performed to reduce the amount of dissolved oxygen in the system, but the bubbling does not have to be performed. From the viewpoint of further increasing the saturation magnetization and relative magnetic permeability and further reducing the coercivity, it is preferable to perform the bubbling.

After the reduction reaction, the soft magnetic nanowire can be purified and recovered by centrifugation, filtration, attraction with a magnet, or the like.

An oxide layer can be formed on the surface of the soft magnetic nanowire by subjecting the soft magnetic nanowire after the reduction reaction or after the purification and recovery to a surface treatment using a basic aqueous solution such as an aqueous sodium hydroxide solution. When the treatment is performed, a nanowire having high purity, high saturation magnetization and relative magnetic permeability, and low coercivity can be obtained without performing bubbling with an inert gas. Subjecting the surface treatment using a basic aqueous solution means that after the reduction reaction, the basic aqueous solution is added to the reaction solution and held for 0.5 to 3 hours, or after the purification and recovery, the soft magnetic nanowire is dispersed in the basic aqueous solution and held for 0.5 to 3 hours.

### First and Second Embodiments: Use and Application of Soft Magnetic Nanowire

The soft magnetic nanowires of the first and second embodiments can be formed into an electromagnetic wave shielding material by being mixed with various materials and subjected to molding processing. The electromagnetic wave shielding material includes: an electromagnetic wave shield such as an electric field shield or a magnetic field shield; and an electromagnetic wave absorber. The electromagnetic wave shield suppresses transmission of electromagnetic waves and reflects electromagnetic waves. The electromagnetic wave absorber suppresses transmission and reflection of electromagnetic waves and absorbs electromagnetic waves. The frequency of the electromagnetic waves shielded by the electromagnetic wave shielding material is, for example, a band of 26.5 to 40 GHz, 70 to 80 GHz, 287.5 to 312.5 GHZ, or the like. The electromagnetic wave shielding material can be used for various applications such as motor cores, electromagnetic valves, and various sensors.

The various materials to be mixed with the soft magnetic nanowires of the first and second embodiments may be organic materials or inorganic materials. In the soft magnetic nanowires of the first and second embodiments, as various materials, for example, a thermosetting resin such as epoxy; a thermoplastic resin such as polyolefin, polyester, and polyamide; rubber such as isoprene rubber or silicone rubber; glass; and ceramic. In addition, a volatile solvent or the like may also be used at the time of mixing. The organic material includes a thermosetting resin, a thermoplastic resin, and rubber.

A molded body containing the soft magnetic nanowires of the first and second embodiments is a molded article that contains the soft magnetic nanowire of the first or second embodiment and the various materials (for example, organic substances), and it may have any shape. The molding processing method is not particularly limited, and examples thereof include a casting method, a melt kneading method, a coating method, an injection molding method, and an extrusion molding method.

As an example of a molded body containing the soft magnetic nanowire of the first or second embodiment, there is a laminated body having a coating film containing the soft magnetic nanowire of the first or second embodiment. For example, a laminated body having a coating film can be formed by applying (and optionally drying) a coating material containing the soft magnetic nanowires of the first and second embodiments onto a substrate. The laminated body of the first and second embodiments can be particularly used for a magnetic field shield, an electromagnetic wave absorber, and the like. The coating material may contain, in addition to the soft magnetic nanowire, the above-described various materials (for example, organic materials) and/or a solvent. The content of the soft magnetic nanowire in the coating material is not particularly limited, and may be, for example, 0.1 to 70 mass %, and is particularly preferably 1 to 50 mass %. The content of the various materials (in particular, organic materials) in the coating material is not particularly limited, and the content may be, for example, 1 to 99 mass %, and is particularly preferably 10 to 90 mass %.

The substrate constituting the laminated body is not particularly limited, and is not particularly limited as long as it can support the coating film. Examples of a material that may constitute the substrate include: organic materials such as polyester, polyamide, and polyimide; inorganic materials such as metal foil, ceramic, and glass; and composite materials thereof.

The coating method for obtaining the laminated body is not particularly limited, and examples thereof include a wire bar coater coating method, a film applicator coating method, a spray coating method, a gravure roll coating method, a screen printing method, a reverse roll coating method, lip coating, an air knife coating method, a curtain flow coating method, an immersion coating method, a die coating method, a spray method, a relief printing method, an intaglio printing method, and an inkjet method.

Another example of the molded body containing the soft magnetic nanowire of the first or second embodiment is, for example, a sheet containing the soft magnetic nanowire of the first or second embodiment. For example, the sheet can be formed by peeling, from a substrate, a sheet obtained by applying (and optionally drying) the coating material containing the soft magnetic nanowire of the first or second embodiment onto the substrate. The sheets of the first and second embodiments may be traded in the market as a single sheet. The sheets of the first and second embodiments can be used for a magnetic field shield, an electromagnetic wave absorber, or the like, as in the case of the laminated body described above. The coating material may contain various materials (for example, an organic material (in particular, polymers or rubbers)) and/or a solvent in addition to the soft magnetic nanowire, as in the case of the coating material for producing the laminated body.

The substrate for obtaining the sheet is not particularly limited as long as the sheet can be peeled off, and the substrate may be selected from substrates within the same range as the substrate constituting the laminated body.

The coating method for obtaining the sheet is not particularly limited, and it may be selected from the same range as the coating method for obtaining the laminated body.

### Third Embodiment: Electromagnetic Wave Absorber

The invention according to the third embodiment relates to an electromagnetic wave absorber. The electromagnetic wave absorber of the third embodiment contains a nanowire (A) and a binder (B).

In the nanowire (A), the content of iron needs to be 65 mass % or more (particularly more than 65 mass %) with respect to the total amount of iron, nickel, and boron. The content of iron is preferably 70 mass % or more from the viewpoint of further improving the electromagnetic wave absorption. To set the content of iron in the nanowire (A) to 65 mass % or more (particularly more than 65 mass %), it is necessary to contain boron. When the content of iron is 65% or more (particularly more than 65 mass %), an increase in coercivity can also be suppressed, and electromagnetic wave absorption efficiently functions in a millimeter wave region that is a high frequency. When the content of iron is too small, the electromagnetic wave absorption deteriorates. Specifically, in any of a band of 26.5 to 40 GHz used for 5G wireless communication (hereinafter, may be abbreviated as “band A”) or a band of 74 to 81 GHz used for a millimeter wave radar (hereinafter, may be abbreviated as “band B”), when the electromagnetic wave absorber is thin (for example, having a thickness of 100 μm), the electromagnetic wave absorption is less than 5 dB, and it cannot be used as an electromagnetic wave absorber. The upper limit value of the content of iron is not particularly limited, and the content of iron may be usually 98 mass % or less (particularly 95 mass % or less).

In the third embodiment, the electromagnetic wave absorption is a characteristic that more sufficiently attenuates or reduces reflection of the electromagnetic wave in at least one band (usually only one band) of the band A or the band B. Specifically, the electromagnetic wave absorption may be the electromagnetic wave absorption in only the band A among the bands A and B, the electromagnetic wave absorption in only the band B, or the electromagnetic wave absorption in both bands. From the viewpoint of more sufficient absorption (for example, further suppression of the reflection) of the electromagnetic wave, the electromagnetic wave absorber of the third embodiment is preferably sufficiently excellent in the electromagnetic wave absorption in only one of the band A and the band B.

The content of nickel in the nanowire (A) is usually 40 mass % or less (particularly 35 mass % or less) with respect to the total amount of iron, nickel, and boron. The lower limit value of the content of nickel is usually 0 mass %, and the content of nickel may be 0 mass % or more.

The content of boron in the nanowire (A) is usually 0.1 mass % or more, and is preferably 0.1 to 15 mass % and more preferably 2.5 to 10 mass % from the viewpoint of further improving the electromagnetic wave absorption. In the present specification, a numerical range R to S (R is any numerical value, and S is any numerical value satisfying R<S) indicates a numerical range including the upper limit value S and the lower limit value R unless otherwise specified.

The content of silver in the nanowire (A) is not particularly limited, and is usually 5 mass % or less (particularly 0 mass %).

In the third embodiment, the content of each element of iron, nickel, silver, and boron in the nanowire (A) may be represented by a proportion to the total content of iron, nickel, and boron calculated by measuring a value (content) (mass %) with respect to the entire amount of the nanowire. As the value (content) of each element with respect to the entire amount of the nanowire, a value measured by subjecting a solution in which the nanowire (A) is dissolved to a multi-element simultaneous analysis method and a calibration curve method both based on an ICP-AES method is used.

The total content of elements other than iron, nickel, silver, and boron in the nanowire (A) is usually 40 mass % or less (particularly 30 mass % or less). The lower limit value of the total content is usually 0 mass %, and the total content may be 0 mass % or more. The elements other than iron, nickel, silver, and boron is elements that are not iron, nickel, silver, or boron contained in the nanowire. Specific examples of the elements other than iron, nickel, silver, and boron include oxygen, carbon, silicon, and cobalt.

The content of the nanowire (A) in the electromagnetic wave absorber needs to be 85 mass % or less, and is usually 25 to 85 mass % with respect to the total of the nanowire (A) and the binder (B). When the content of the nanowire (A) is too small or too large, in both of the band A and the band B, the electromagnetic wave absorption is less than 5 dB, and the electromagnetic wave absorber cannot be used as an electromagnetic wave absorber when the thickness is small (for example, having a thickness of 100 μm).

The electromagnetic wave absorption largely depends on the content of iron in the nanowire (A) and the content of the nanowire (A) in the electromagnetic wave absorber. Thus, the third embodiment includes the following aspects A to C from the viewpoint of preferable electromagnetic wave absorption.

Aspect A: The electromagnetic wave absorption in the band A can be further improved by setting the content of iron in the nanowire (A) to 65 mass % or more and less than 80 mass % (particularly 65 to 75 mass %) and setting the content of the nanowire (A) to 45 to 85 mass % (particularly 48 to 82 mass %) with respect to the total of the nanowire (A) and the binder (B). In this aspect, the content of each element of nickel, silver, and boron may be within the above range, and for example, the contents of nickel, silver, and boron may be 5 to 30 mass % (particularly 10 to 30 mass %), 0 to 2 mass % (particularly 0 mass %), and 1 to 15 mass % (particularly 3 to 10 mass %), respectively. In this aspect, the total content of elements other than iron, nickel, silver, and boron in the nanowire (A) may be within the above range, and the total content may be, for example, 5 to 30 mass % (particularly 10 to 20 mass %).

Aspect B: The electromagnetic wave absorption in the band B can be further improved by setting the content of iron in the nanowire (A) to 80 to 95 mass % (particularly 84 to 95 mass %) and setting the content of the nanowire (A) to 45 to 85 mass % (particularly 48 to 82 mass %) with respect to the total of the nanowire (A) and the binder (B). In this aspect, the content of each element of nickel, silver, and boron may be within the above range, and for example, the contents of nickel, silver, and boron may be 0 to 20 mass % (particularly 0 to 10 mass %), 0 to 2 mass % (particularly 0 mass %), and 1 to 15 mass % (particularly 2 to 10 mass %), respectively. In this aspect, the total content of elements other than iron, nickel, silver, and boron in the nanowire (A) may be within the above range, and the total content may be, for example, 0 to 40 mass % (particularly 0 to 30 mass %).

Aspect C: The electromagnetic wave absorption in the band B can be further improved by setting the content of iron in the nanowire (A) to 65 mass % or more and less than 80 mass % (particularly 65 to 75 mass %) and setting the content of the nanowire (A) to 25 mass % or more and less than 45 mass % (particularly 28 to 42 mass %) with respect to the total of the nanowire (A) and the binder (B). In this aspect, the content of each element of nickel, silver, and boron may be within the above range, and for example, the contents of nickel, silver, and boron may be 5 to 30 mass % (particularly 10 to 30 mass %), 0 to 2 mass % (particularly 0 mass %), and 1 to 15 mass % (particularly 3 to 10 mass %), respectively. In this aspect, the total content of elements other than iron, nickel, silver, and boron in the nanowire (A) may be within the above range, and the total content may be, for example, 5 to 30 mass % (particularly 10 to 20 mass %).

To absorb noise in a range from a quasi-millimeter wave to a millimeter wave, a material having high dielectric constant and magnetic permeability is normally used, and noise energy is converted into thermal energy and lost. Thus, in the third embodiment, the nanowire (A) that is a magnetic material and the binder (B) that is a dielectric material are used to increase the dielectric constant and the magnetic permeability.

Since noise is absorbed inside the material by the electromagnetic wave absorber, a thick electromagnetic wave absorber is advantageous, but an electromagnetic wave absorber that can be used with a small thickness is desired to be used for AiP that is becoming smaller in size. Thus, in the third embodiment, a metal nanowire having high saturation magnetization and high magnetic permeability of the nanowire itself in which the content of iron is within the above range is used. The mass ratio of iron or the like in the nanowire can be measured by an ICP-AES method as described above. Whether the nanowire is metal may be evaluated by XRD.

Since a demagnetizing field is generated inside the magnetic material, for example, a single particle of magnetic particles is hardly magnetized in an alternating magnetic field, and high filling and alignment of the magnetic particles are essential. However, the nanowire (A) of the third embodiment has high anisotropy, in which the S pole and the N pole are distant from each other, and thus a demagnetizing field hardly effects. Thus, even a single nanowire is easily magnetized. As a result, it is possible to obtain an electromagnetic wave absorber having a wide absorption band different from that of an electromagnetic wave absorber containing magnetic particles requiring high filling and alignment.

Further, the nanowire (A) has a characteristic of easily forming clusters inside the material because the percolation threshold is lowered due to its fibrous shape having high anisotropy. In the case of a particulate conductive material such as carbon, high filling is required to increase the dielectric constant of the material (electromagnetic wave absorber), but when the filling rate increases, interface impedance between the material and the space is mismatched, and noise is reflected. Thus, it does not function as an electromagnetic wave absorber. Specifically, an electromagnetic wave absorber containing a particulate conductive material hardly exhibits electromagnetic wave absorption. The nanowire (A) of the third embodiment can increase the dielectric constant inside the material even with a small addition amount. Moreover, since the addition amount is small, a structure like a skin layer in molding processing can be easily formed, and the difference in interface impedance between the material and the space can be alleviated. As a result, it becomes likely to function as an electromagnetic wave absorber. Specifically, in the third embodiment, the electromagnetic wave absorber more sufficiently exhibits electromagnetic wave absorption.

The average length of the nanowire (A) of the third embodiment is not particularly limited, and is preferably 30 μm or less, more preferably 25 μm or less, and more preferably 18 μm or less from the viewpoint of further improving the electromagnetic wave absorption and improving the handling in the nanowire production process. The lower limit of the average length is not particularly limited either, and the average length is usually 3 μm or more, and more preferably 5 μm or more.

The average diameter of the nanowire (A) of the third embodiment is not particularly limited, and for example, the average diameter may be about 50 nm to 200 nm (particularly 50 to 120 nm) from a viewpoint of preferable production. In the third embodiment, since anisotropy is important, the relationship (for example, the value thereof) of average length/average diameter in the nanowire (A) is preferably 50 or more, and more preferably 100 or more from the viewpoint of further improving the electromagnetic wave absorption. In the case of the particulate form, the demagnetizing factoris 0.33, but when the relationship of the average length/average diameter is 50, the demagnetizing factor in a major axis direction is about 0.0014, and when the relationship of the average length/average diameter is 100, the demagnetizing factor in the major axis direction is about 0.00043. Thus, when the average length/average diameter is in the above range, the demagnetizing factor is sufficiently small, and the expected effect can be more sufficiently obtained. The upper limit of the average length/average diameter is not particularly limited, and the average length/average diameter may be 300 or less (particularly 220 or less).

Producing the nanowire (A) in a magnetic field makes it possible to match the shape and the magnetocrystalline anisotropy. An example of the production method is shown below.

To form the nanowire (A) in a magnetic field, the metal salts of the raw materials are reduced with a reducing agent. The metal salts of the raw materials are chloride, nitrate, sulfate, acetate, and the like of each metal, and they may be reacted in a solution having a concentration of about 50 mmol/L. The content of iron can be controlled by the ratio of the metal salts of the raw materials. For example, to set the amount of iron to 50 mass %, the ratio of iron in metals contained in all metal salts may be set to 50 mass %.

As the reducing agent used in the reduction reaction, a reducing agent containing boron (for example, sodium borohydride) is used. For example, reducing the metal salt around room temperature using sodium borohydride makes the reduction reaction rate and the time related to the reaction become conditions suitable for forming the nanowire. When the concentration of sodium borohydride used in the reaction is higher than the concentration of the metal salt, the nanowire (A) can be obtained in a high yield.

The magnetic field applied during the reduction reaction may be about 50 to 160 mT (particularly 50 to 150 mT). In the case of a lower magnetic field, a nanowire does not form in some cases. In the case of a stronger magnetic field, the generated nanowire is attracted to the source of the magnetic field and is not recovered in some cases.

In the reduction reaction, bubbling with an inert gas such as nitrogen or argon may be performed to reduce the amount of dissolved oxygen in the system, but the bubbling does not have to be performed. From the viewpoint of further improving the electromagnetic wave absorption, it is preferable to perform the bubbling.

The time from the addition of the reducing agent to the generation of the nanowire is about several seconds. A nanowire containing a large amount of iron may be reionized and return to iron ions depending on the conditions of the aqueous solution. Thus, the formation of passivation on the nanowire surface can be promoted by adding an aqueous sodium hydroxide solution or the like, adjusting the pH of the reaction solution to 12 to 13, and holding the reaction solution for 30 minutes or more so that the nanowire can be stabilized. Thereafter, the nanowire may be recovered with a filter or the like and purified.

The third embodiment does not prevent the electromagnetic wave absorber from containing a nanowire (hereinafter, may be referred to as “other nanowires”) other than the nanowire (A). The content of the other nanowires may be, for example, 10 mass % or less (particularly 1 mass % or less) with respect to the nanowire (A). The electromagnetic wave absorber of the third embodiment preferably does not contain other nanowires from the viewpoint of further improving the electromagnetic wave absorption.

The binder (B) is not particularly limited as long as it binds the nanowire (A) to form a high dielectric material. The binder may be appropriately selected according to properties required as an electromagnetic wave absorber such as heat resistance and flexibility. Examples of the binder include: polymer materials such as silicone resin; various types of rubber such as polyisoprene; epoxy resin; acrylic resin; fluorine resin; polyolefin resin; polyester resin; mixtures thereof; and ceramic materials such as silica. The molecular weight of the polymer material is not particularly limited as long as the nanowire (A) can be bound, and the molecular weight may be, for example, a molecular weight of an ordinary polymer material of about 10,000 to 1,000,000, or the polymer material may be a polymer material having a crosslinked structure.

The electromagnetic wave absorber of the third embodiment may contain additives such as a flame retardant, a UV absorber, and an antioxidant.

The shape of the electromagnetic wave absorber of the third embodiment is not limited, and the electromagnetic wave absorber of the third embodiment may have, for example, a film shape, a sheet shape, or a plate shape.

When the electromagnetic wave absorber of the third embodiment has a film shape, a sheet shape, or a plate shape as described above, the thickness thereof is not particularly limited, and the thickness may be, for example, 1 mm or less, particularly 1 to 1000 μm, preferably 10 to 500 μm, and more preferably 50 to 200 μm. The electromagnetic wave absorber of the third embodiment having such a thickness can exhibit more sufficient electromagnetic wave absorption in the application described later.

The process for producing the electromagnetic wave absorber of the third embodiment is not particularly limited as long as the nanowire (A) and the binder (B) can be mixed, but it is preferable that cutting of the nanowire does not occur. Thus, it is preferable to mix the nanowire (A) and the binder (B) preferably in a liquid state. The liquid state includes not only a state of containing water or a solvent but also a state of being mixed with a monomer (for example, an epoxy monomer) of a binder.

The electromagnetic wave absorber can be obtained by forming a coating film by spraying or coating a mixed liquid (for example, ink) containing the nanowire (A) and the binder (B). The content of the nanowire (A) contained in the electromagnetic wave absorber may be designed according to the application and purpose, but in order to be an electromagnetic wave absorber, the content of the nanowire is set within the above-described range. As described above, when the content of the nanowire is large, interface impedance mismatch occurs, and noise is reflected. The electromagnetic wave absorber of the third embodiment may be obtained by heat-pressing a mixture containing the nanowire (A) and the binder (B).

The mixed liquid containing the nanowire (A) and the binder (B) may contain additives such as a leveling agent, a defoaming agent, and a thickener for improving processability.

To adapt the electromagnetic wave absorber of the third embodiment to AiP to be miniaturized, which is the object of the third embodiment, it is suitable to use the electromagnetic wave absorber with a thickness of 1 mm or less (particularly, less than 1 mm). For example, the thickness of AiP including a millimeter wave antenna used for a smartphone is about 4 mm, and it is considered unsuitable that the thickness exceeds 1 mm only with the electromagnetic wave absorber.

The electromagnetic wave absorber of the third embodiment is suitable for a millimeter wave, and thus can be referred to as “millimeter wave absorber”. The millimeter wave is an electromagnetic wave having a wavelength of 1 to 10 mm, and may be, for example, an electromagnetic wave of 1 to 300 GHz, particularly 1 to 100 GHz in a frequency band. The electromagnetic wave absorber of the third embodiment may be designed to exhibit absorption performance suitable for each application. Typical applications using millimeter waves are millimeter wave antennas in 5G and millimeter wave radars of automobiles.

A frequency band used for 5G wireless communication is about 26.5 to 40 GHz. For example, in the case of the electromagnetic wave absorber of the third embodiment, in this region, the electromagnetic wave absorber having a thickness of 100 μm can achieve absorption of about 5 dB or more, preferably about 10 dB or more, and more preferably about 15 dB or more as an average value. For example, absorption of 15 dB means that 97% of noise energy can be absorbed.

The frequency band used for a millimeter wave radar will be 76 GHz in the future for general-purpose use and 79 GHz for high resolution radar, and it is ideal that a millimeter wave can be absorbed in a band of 74 to 81 GHz. The electromagnetic wave absorber of the third embodiment can achieve absorption of about 5 dB or more, preferably about 10 dB or more, and more preferably about 15 dB or more as an average value with a thickness of 100 μm in this region (band).

The electronic wave absorber of the third embodiment can also provide an antenna unit for wireless communication including the electronic wave absorber in a package and a sensing unit including the electronic wave absorber in a package.

An antenna unit for wireless communication of the third embodiment includes the electromagnetic wave absorber of the third embodiment in a package (that is, a housing). For example, parts other than a transmission/reception unit (typical antenna part) of the antenna unit are covered with the electromagnetic wave absorber of the third embodiment. Alternatively, the electromagnetic wave absorber of the third embodiment is attached to an electronic component such as an integrated circuit (RFIC) in which coupling is to be suppressed. This makes it possible for the antenna unit for wireless communication to suppress deterioration of reception sensitivity and the like, and exhibit original performance such as high-speed communication. The package body may be made of any material, and examples thereof include a molding material of a polymer material and a metal case.

A sensing unit of the third embodiment includes the electromagnetic wave absorber of the third embodiment in a package (that is, a housing). For example, for example, parts other than a transmission/reception unit (typical antenna part) of the sensing unit are covered with the electromagnetic wave absorber of the third embodiment. Alternatively, the electromagnetic wave absorber of the third embodiment is attached to an electronic component such as an integrated circuit (MMIC) in which coupling is to be suppressed. This makes it possible for the sensing unit to suppress deterioration of detection sensitivity and the like and exhibit high resolution sensing performance. The package body may be made of any material, and examples thereof include a molding material of the polymer material described above and a metal case.

Although the case where the electromagnetic wave absorber of the third embodiment includes the nanowire (A) and the binder (B) has been described above, the electromagnetic wave absorber of the third embodiment may contain the soft magnetic nanowire of the invention according to the first and second embodiments described above instead of the nanowire (A) or in addition to the nanowire (A).

### EXAMPLES

Hereinafter, the present invention will be specifically described with reference to Examples, but the present invention is not limited to Examples. Experimental Examples 1 to 3 below correspond to the first to third embodiments described above, respectively.

### Experimental Example 1 (First Embodiment)

### (1) Nanowire Formation

The obtained product was subjected to vacuum drying, then observed with a microscope, and photographed at a magnification of 100,000 times using a scanning electron microscope (SEM). The length and diameter of the nanowires were measured at any 100 points in any 10 fields of views, and the average value was calculated for each of the length and diameter. The aspect ratio was calculated by dividing the average length by the average diameter. Based on the aspect ratio, the shape was evaluated according to the following criteria.
◯: Fibrous (aspect ratio of 10 or more);
X: Non-fibrous (aspect ratio less than 10);
XX: Neither fibrous nor non-fibrous products were obtained.

### (2) Average Length, Average Diameter, and Aspect Ratio of Nanowire

In the above item (1), when a fibrous product was obtained, the average length, average diameter, and aspect ratio of the nanowires were shown.

The average length of the nanowires was evaluated according to the following criteria.
⊙: 10 μm or more (excellent); ◯: 5 μm or more and less than 10 μm (good);
X: less than 5 μm (having a problem in practical use)

### (3) Molar Ratio of Nanowire

The obtained product was subjected to vacuum drying and photographed at a magnification of 100,000 times using a scanning electron microscope (SEM). The constituent ratio of each element was measured by an EDS method in any 10 fields of view, and the molar ratio of iron/boron was calculated.

The molar ratio of iron/boron in the nanowire was evaluated according to the following criteria.
⊙⊙: less than 3 (best);
⊙: 3 or more and less than 4 (excellent);
◯: 4 or more and less than 5 (good);
X: 5 or more (having a problem in practical use)

### (4) Constituent Ratio (Mass Ratio) and Total Amount

The obtained product was subjected to vacuum drying and then dissolved in a mixed solution of dilute hydrochloric acid and dilute nitric acid. The obtained solution was subjected to a multi-element simultaneous analysis method of an ICP-AES method to confirm the presence or absence of boron, silicon, and other metal elements. Examples of other metal elements include iron, cobalt, and nickel, and metal elements other than these metal elements were not confirmed. The detection limit value of each metal element was 0.1 mass %.

When silicon was not detected, the contents of iron, cobalt, nickel, and boron were quantified by an ICP-AES method with a calibration curve using a standard solution of iron, cobalt, nickel, and boron.

When silicon was detected, the contents of iron, cobalt, nickel, boron, and silicon were quantified by an ICP-AES method with a calibration curve using a standard solution of iron, cobalt, nickel, boron, and silicon.

The quantified content of each element was shown as a proportion to the entire amount (100 mass %) of the nanowire ((1) in Table 1).

From the quantified content of each element, the “Content of each element of Fe, Co, Ni, B, and Si with respect to total content X” ((2) in Table 1) and the “Proportion of total content X to entire amount of nanowire” ((3) in Table 1) in the nanowire were calculated.

The content other than iron, cobalt, nickel, boron, and silicon in the nanowire can be determined by subtracting the content of iron, cobalt, nickel, boron, and silicon from the mass of the nanowire.

### (5) Magnetic Properties (Saturation Magnetization, Relative Magnetic Permeability, and Coercivity)

The obtained product was subjected to vacuum drying, and then the magnetic properties were determined by a vibrating-sample magnetometer (VSM). The measurement was performed at room temperature (25° C.). The measurement was performed in a state where the product was not oriented.

The saturation magnetization was evaluated according to the following criteria.
⊙⊙: 150 emu/g or more (best);
⊙: 60 emu/g or more and less than 150 emu/g (excellent);
◯: 40 emu/g or more and less than 60 emu/g (good);
X: less than 40 emu/g (having a problem in practical use)

The relative magnetic permeability was evaluated according to the following criteria.
⊙⊙: 100 or more (best);
⊙: 40 or more and less than 100 (excellent);
◯: 10 or more and less than 40 (good);
Δ: 5 or more and less than 10 (acceptable, having no problem in practical use);
X: less than 5 (having a problem in practical use)

The coercivity was evaluated according to the following criteria.
⊙⊙: less than 200 Oe (best);
⊙: 200 Oe or more and less than 400 Oe (excellent);
◯: 400 Oe or more and less than 500 Oe (good);
X: 500 Oe or more (having a problem in practical use)

### (6) Overall Evaluation of Magnetic Properties

The evaluation results of the magnetic properties (saturation magnetization, relative magnetic permeability, and coercivity) described above were comprehensively evaluated. Specifically, the lowest evaluation result among these evaluation results was used as the result of comprehensive evaluation.
⊙⊙: Best;
⊙: Excellent;
◯: Good;
Δ: Acceptable (having no problem in practical use);
X: Not acceptable (having a problem in practical use)

### (7) Dissolved Oxygen Concentration in Reaction Solution

Measurement was performed at 25° ° C. under atmospheric pressure using DO meter B-506 manufactured by Iijima Electronics Corporation.

### Example 1-1

In 300 parts by mass of water, 8.55 parts by mass (43 molar parts) of iron (II) chloride tetrahydrate was dissolved, the solution was placed in a magnetic circuit having a central magnetic field of 130 mT, and nitrogen gas bubbling was started. After a lapse of 10 minutes from the start of bubbling, it was confirmed that the amount of dissolved oxygen was 2 mg/L, and then dropwise addition of an aqueous solution obtained by dissolving 7.00 parts by mass (185 molar parts) of sodium borohydride in 175 parts by mass of water was started. The aqueous solution was added dropwise over 15 minutes, and then left to stand still for 10 minutes. The concentrations of the iron ions and the reducing agent in the reaction solution were as follows: (iron ion 91 mmol/L, reducing agent 389 mmol/L).

Thereafter, the application of the magnetic field and the nitrogen gas bubbling were stopped, and the reaction solution was poured into 200 parts by mass of water to dilute. The generated black nanowire was collected by filtration using a PTFE filter T100A090C, washed three times with water and three times with methanol, and subjected to vacuum drying for 24 hours at room temperature to obtain a nanowire.

### Example 1-2

A nanowire was obtained by the same operation as in Example 1-1 except that the time taken for the dropwise addition of the aqueous sodium borohydride solution was 10 minutes.

### Example 1-3

In 175 parts by mass of water, 7.00 parts by mass (185 molar parts) of sodium borohydride was dissolved, the solution was placed in a magnetic circuit having a central magnetic field of 130 mT, and nitrogen gas bubbling was started. After a lapse of 10 minutes from the start of bubbling, it was confirmed that the amount of dissolved oxygen was 2 mg/L, and then dropwise addition of an aqueous solution obtained by dissolving 8.55 parts by mass (43 molar parts) of iron (II) chloride tetrahydrate in 300 parts by mass of water was started. The aqueous solution was added dropwise over 10 minutes, and then left to stand still for 10 minutes.

Thereafter, the application of the magnetic field and the nitrogen gas bubbling were stopped, and the reaction solution was poured into 200 parts by mass of water to dilute. The generated black nanowire was collected by filtration using a PTFE filter T100A090C, washed three times with water and three times with methanol, and subjected to vacuum drying for 24 hours at room temperature to obtain a nanowire.

### Example 1-4

A nanowire was obtained by the same operation as in Example 1-1 except that iron (II) chloride tetrahydrate as a raw material was changed to iron (III) chloride hexahydrate.

### Example 1-5

In 300 parts by mass of water, 8.55 parts by mass (43 molar parts) of iron (II) chloride tetrahydrate was dissolved, and the solution was placed in a magnetic circuit opened to the atmosphere and having a central magnetic field of 130 mT. After it was confirmed that the amount of dissolved oxygen was 7 mg/L, dropwise addition of an aqueous solution obtained by dissolving 7.00 parts by mass (185 molar parts) of sodium borohydride in 175 parts by mass of water was started without performing bubbling. The aqueous solution was added dropwise over 15 minutes, and then left to stand still for 10 minutes. A 20% aqueous sodium hydroxide solution was added to the obtained reaction solution to adjust the pH to 12 to 13, and the reaction solution was allowed to stand for 1 hour.

Thereafter, the application of the magnetic field was stopped, and the reaction solution was poured into 200 parts by mass of water to dilute. The generated black solid was collected by filtration using a PTFE filter T100A090C, washed three times with water and three times with methanol, and subjected to vacuum drying for 24 hours at room temperature to obtain a nanowire.

### Comparative Example 1-1

In 300 parts by mass of water, 8.55 parts by mass (43 molar parts) of iron (II) chloride tetrahydrate was dissolved, and the solution was placed in a magnetic circuit opened to the atmosphere and having a central magnetic field of 130 mT. After it was confirmed that the amount of dissolved oxygen was 7 mg/L, dropwise addition of an aqueous solution obtained by dissolving 7.00 parts by mass (185 molar parts) of sodium borohydride in 175 parts by mass of water was started. The aqueous solution was added dropwise over 15 minutes, and then left to stand still for 10 minutes.

Thereafter, the application of the magnetic field was stopped, and the reaction solution was poured into 200 parts by mass of water to dilute. The generated black solid was collected by filtration using a PTFE filter T100A090C, washed three times with water and three times with methanol, and subjected to vacuum drying for 24 hours at room temperature to obtain a nanowire.

### Comparative Example 1-2

In 300 parts by mass of water, 8.55 parts by mass (43 molar parts) of iron (II) chloride tetrahydrate was dissolved, and the solution was placed in a reaction vessel to which a magnetic field of 150 mT was applied. As a deoxygenating agent, 0.5 parts by mass of hydrazine monohydrate was added, and it was confirmed that the amount of dissolved oxygen was 0.2 mg/L. Thereafter, dropwise addition of an aqueous solution obtained by dissolving 7.00 parts by mass (185 molar parts) of sodium borohydride in 175 parts by mass of water was started. The aqueous solution was added dropwise over 15 minutes, and then left to stand still for 10 minutes. Thereafter, the application of the magnetic field was stopped, and the reaction solution was poured into 200 parts by mass of water to dilute.

The generated black solid was collected by filtration using a PTFE filter T100A090C, washed three times with water and three times with methanol, and subjected to vacuum drying for 24 hours at room temperature to obtain yellow particles having an indefinite shape.

### Comparative Example 1-3

A solution A was prepared by dissolving 1.00 parts by mass of sodium hydroxide in 472 parts by mass of ethylene glycol and heating the solution to 90° C. A solution B was prepared by dissolving 3.34 parts by mass (16.9 molar parts) of iron (II) chloride tetrahydrate in 99.3 parts by mass of ethylene glycol. The solution A, 25.0 parts by mass of 28% aqueous ammonia, the solution B, and 2.50 parts by mass of hydrazine monohydrate were added in this order to a reaction vessel heated to 90 to 95° C. The addition of each liquid was performed at intervals of 10 seconds in the above order while stirring. After addition of all of them, a magnetic field of 150 mT was applied, and the obtained mixture was allowed to stand at 90 to 95° C. for 90 minutes, but the reaction did not proceed and no product was obtained.

The evaluation results of the products obtained in Examples and Comparative Examples of Experimental Example 1 are shown in Table 1.

TABLE 1
Experimental Example 1 (First Embodiment)

| | | | | | | | | | | | Con- | | | | | | | | | | | | | | |
|---|---|---|---|---|---|---|---|---|---|---|---|---|---|---|---|---|---|---|---|---|---|---|---|---|---|
| | | | | | | | | | | | stituent | | | | | | | | | | | | | | |
| | | | | | | | | | | | ratio | | | | | | | | | | | | | | |
| | Production conditions | | | | | | | | | | magnetic | | | | | | | | | | | Magnetic properties | | | |
| | | | | Drop- | Amount | | | | | | ratio) | | Constituent | | | | | | | | | Satura- | Rel- | | |
| | | | | ping | of | | Nano- | Nanowire | | | by | | ratio | | | Constituent ratio | | | | | Total | tion | ative | | Over- |
| | | Re- | | rate | dissolved | Basic | wire | Average | Average | As- | SEM- | | (mass ratio) | | | (mass ratio) | | | | | a- | magne- | perme- | Coer- | all |
| | | ducing | Dropped | (mass | oxygen | treat- | forma- | length | diameter | pect | EDS | | by ICP-AES (1) | | | by ICP-AES (2) | | | | | mount | tization | ability | civity | evalu- |
| | Salt | agent | solution | %/min) | (mg/L) | ment | tion | μm | nm | ratio | Fe/B | | Fe | B | Others | Fe | Ni | Co | B | Si | (3) | emu/g | — | Oe | ation |
| Ex- | FeCl₂ | NaBH₄ | Re- | 6.7 | 2 | None | ◯ | 12⊚ | 70 | 171 | 2.1 | ⊚⊚ | 94.8 | 5.2 | <0.1 | 94.8 | 0 | 0 | 5.2 | 0 | 100 | 161 | 119 | 150 | ⊚⊚ |
| ample | | | ducing | | | | | | | | | | | | | | | | | | | ⊚⊚ | ⊚⊚ | ` | |
| 1-1 | | | agent | | | | | | | | | | | | | | | | | | | | | | |
| Ex- | FeCl₂ | NaBH₄ | Re- | 10 | 2 | None | ◯ | 14⊚ | 148 | 95 | 3.5 | ⊚ | 92.2 | 3.7 | 4.1 | 96.0 | 0 | 0 | 3.9 | 0.1 | 96.0 | 165 | 58⊚ | 211⊚ | ⊚ |
| ample | | | ducing | | | | | | | | | | | | | | | | | | | ⊚⊚ | | | |
| 1-2 | | | agent | | | | | | | | | | | | | | | | | | | | | | |
| Ex- | FeCl₂ | NaBH₄ | Salt | 6.7 | 2 | None | ◯ | 5◯ | 114 | 44 | 2.4 | ⊚⊚ | 88.0 | 4.8 | 7.2 | 94.6 | 0 | 0 | 5.2 | 0.2 | 93.0 | 144⊚ | 45⊚ | 187 | ⊚ |
| ample | | | | | | | | | | | | | | | | | | | | | | | | ⊚⊚ | |
| 1-3 | | | | | | | | | | | | | | | | | | | | | | | | | |
| Ex- | FeCl₂ | NaBH₄ | Re- | 6. | 2 | None | ◯ | 13⊚ | 104 | 125 | 2.8 | ⊚⊚ | 77.9 | 5.0 | 17.1 | 93.9 | 0 | 0 | 6.0 | 0.1 | 83.0 | 120⊚ | 20◯ | 370⊚ | ◯ |
| ample | | | ducing | | | | | | | | | | | | | | | | | | | | | | |
| 1-4 | | | agent | | | | | | | | | | | | | | | | | | | | | | |
| Ex- | FeCl₂ | NaBH₄ | Re- | 6.7 | 7 | Per- | ◯ | 14 | 95 | 151 | 2.8 | ⊚⊚ | 90 | 4.9 | 5.1 | 94.8 | 0 | 0 | 5.1 | 0.1 | 95.0 | 156 | 167 | 161 | ⊚⊚ |
| ample | | | ducing | | | formed | | | | | | | | | | | | | | | | ⊚⊚ | | ⊚⊚ | |
| 1-5 | | | agent | | | | | | | | | | | | | | | | | | | | ⊚⊚ | | |
| Com- | FeCl₂ | NaBH₄ | Re- | 6.7 | 7 | None | ◯ | 4X | 60 | 67 | 4.6 | ◯ | 68.5 | 3.4 | 28.1 | 95.1 | 0 | 0 | 4.8 | 0.1 | 72.0 | 38X | 6Δ | 255⊚ | X |
| parative | | | ducing | | | | | | | | | | | | | | | | | | | | | | |
| Ex- | | | agent | | | | | | | | | | | | | | | | | | | | | | |
| ample | | | | | | | | | | | | | | | | | | | | | | | | | |
| 1-1 | | | | | | | | | | | | | | | | | | | | | | | | | |
| Com- | FeCl₂ | NaBH₄ | Re- | 6.7 | 0.2 | None | ◯ | 10⊚ | 70 | 143 | 5.4 | X | 58.4 | 2.5 | 39.1 | 95.7 | 0 | 0 | 4.2 | 0.1 | 61.0 | 22X | 4X | 182 | X |
| parative | | | ducing | | | | | | | | | | | | | | | | | | | | | ⊚⊚ | |
| Ex- | | | agent | | | | | | | | | | | | | | | | | | | | | | |
| ample | | | | | | | | | | | | | | | | | | | | | | | | | |
| 1-2 | | | | | | | | | | | | | | | | | | | | | | | | | |
| Com- | FeCl₂ | NaBH₄ | — | — | — | None | XX | — | — | — | — | — | — | — | — | — | — | — | — | — | — | — | — | — | — |
| parative | | | | | | | | | | | | | | | | | | | | | | | | | |
| Ex- | | | | | | | | | | | | | | | | | | | | | | | | | |
| ample | | | | | | | | | | | | | | | | | | | | | | | | | |
| 1-3 | | | | | | | | | | | | | | | | | | | | | | | | | |

(1) Proportion (mass ratio) with respect to entire amount of nanowire,
(2) Proportion (mass ratio) of Fe, Ni, Co, B, and Si with respect to total content X,
(3) Proportion of total content X of Fe, Ni, Co, B and Si in nanowire (proportion with respect to entire nanowire) (mass %)

The soft magnetic nanowires of Examples 1-1 to 1-5 had an iron/boron molar ratio of less than 5, a long average length, a sufficiently high saturation magnetization and relative magnetic permeability and a sufficiently low coercivity, and the performance as a soft magnetic material was sufficiently excellent.

The nanowire of Comparative Example 1-1 had a low purity of iron, a short average length, a low saturation magnetization and relative magnetic permeability and a high coercivity, and the performance as a soft magnetic material was poor.

In Comparative Example 1-2, a deteriorated product having an indefinite shape was observed, the molar ratio of iron/boron was 5 or more, the purity of iron was low, the saturation magnetization and relative magnetic permeability were low, and the performance as a soft magnetic material was poor.

In Comparative Example 1-3, since boron was not contained, the reduction reaction did not proceed, and no product was obtained.

### Experimental Example 2 (Second Embodiment)

### (1) Nanowire Formation

The average length and average diameter of the nanowires were measured in the same manner as in the method for evaluating nanowire formation in Experimental Example 1, and the aspect ratio was calculated and evaluated.

### (2) Average Length, Average Diameter, and Aspect Ratio of Nanowire

In the above item (1) of Experimental Example 2, when a fibrous product was obtained, the average length, average diameter, and aspect ratio of the nanowire were shown. The average length of the nanowires was evaluated according to the same criteria as the criteria in Experimental Example 1.

### (3) Constituent Ratio (Mol %)

When a fibrous or non-fibrous product was obtained in the item (1) of Experimental Example 2, the constituent ratio of each element was measured by the same method as the method for evaluating the molar ratio of a nanowire in Experimental Example 1, and the molar ratio of iron, cobalt, nickel, and boron was calculated. The molar ratio of iron/boron was evaluated according to the same criteria as the criteria in Experimental Example 1 ((1) in Table 2).

### (4) Crystallinity

When a fibrous product was obtained in the item (1) of Experimental Example 2, the obtained nanowire was measured by a WAXD reflection method, and whether a crystalline peak was observed was determined according to the following criteria. The “peak” is a sharp diffraction pattern as shown in Comparative Example 2-2 of FIG. 2, and the “halo” is a broad diffraction pattern as shown in Examples 2-1, 2-2, and 2-4 of FIG. 2. FIG. 2 is a diagram showing a chart of a WAXD reflection method of Examples 2-1, 2-2, 2-4, and Comparative Example 2-2.
◯: No crystalline peak was observed, and only a halo was observed.
X: A crystalline peak was observed.

### (5) Constituent Ratio (Mass Ratio) and Total Amount

The contents of iron, cobalt, nickel, boron, and silicon were quantified by the same method as the method for evaluating the constituent ratio (mass ratio) and the total amount in Experimental Example 1.

From the quantified content of each element, the “Content of each element of Fe, Co, Ni, B, and Si with respect to total content X” ((2) in Table 2) and the “Proportion of total content X to entire amount of nanowire” ((3) in Table 2) in the nanowire were calculated.

The content other than iron, cobalt, nickel, boron, and silicon in the nanowire can be determined by subtracting the content of iron, cobalt, nickel, boron, and silicon from the mass of the nanowire.

### (6) Magnetic Properties (Saturation Magnetization, Relative Magnetic Permeability, and Coercivity)

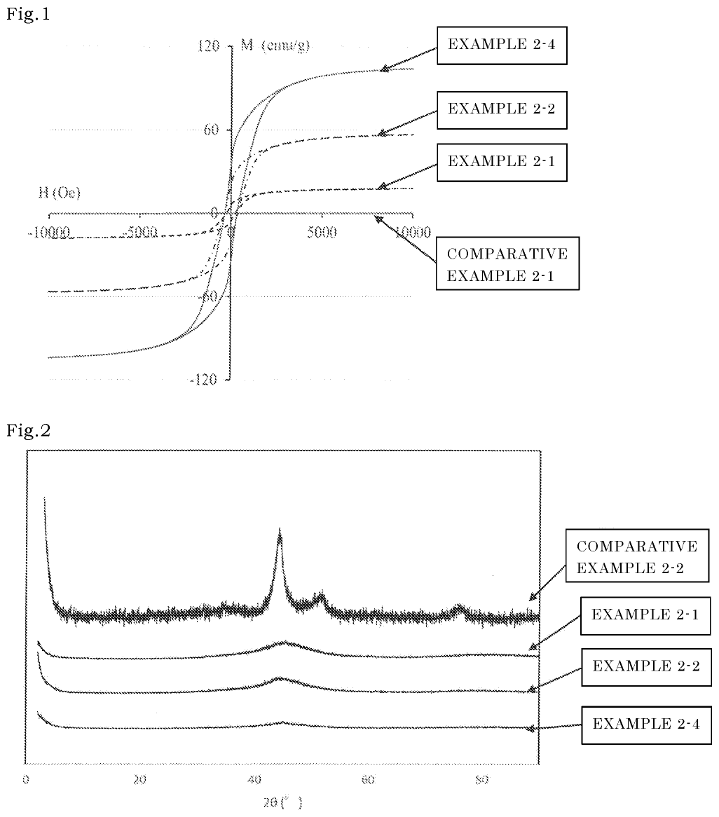

Measurement and evaluation were performed in the same manner as in the measurement method and evaluation method of magnetic properties (saturation magnetization, relative magnetic permeability, and coercivity) in Experimental Example 1. The magnetization curves of Examples 2-1, 2-2, 2-4, and Comparative Example 2-1 are illustrated in FIG. 1.

### (7) Overall Evaluation of Magnetic Properties

The evaluation results of the magnetic properties (saturation magnetization, relative magnetic permeability, and coercivity) described above were comprehensively evaluated. Specifically, the magnetic properties were evaluated by the same method as the evaluation method of comprehensive evaluation of magnetic properties in Experimental Example 1.

### Example 2-1

In 300 parts by mass of water, 4.27 parts by mass (21.5 molar parts) of iron (II) chloride tetrahydrate and 5.12 parts by mass (21.5 molar parts) of nickel chloride hexahydrate were dissolved, the solution was placed in a magnetic circuit having a central magnetic field of 130 mT (molar ratio of iron (II) chloride tetrahydrate: nickel chloride hexahydrate was 50:50), and nitrogen gas bubbling was started. After a lapse of 10 minutes from the start of bubbling, dropwise addition of an aqueous solution obtained by dissolving 7.00 parts by mass (185 molar parts) of sodium borohydride (containing 0.1 mass % of silicon) in 175 parts by mass of water was started. The aqueous solution was added dropwise over 15 minutes, and then left to stand still for 10 minutes. The concentrations of the metal ions and the reducing agent in the reaction solution were as follows: (iron ion 45 mmol/L, nickel ion 45 mmol/L, reducing agent 389 mmol/L).

The application of the magnetic field and the nitrogen gas bubbling were stopped, and the reaction solution was poured into 200 parts by mass of water to dilute. The generated black solid was collected by filtration using a PTFE filter “T100A090C”, washed three times with water and three times with methanol, and subjected to vacuum drying for 24 hours at room temperature to obtain a nanowire.

### Examples 2-2 to 2-8

Each nanowire was obtained by performing the same operation as in Example 2-1 except that the feeding ratio of iron (II) chloride tetrahydrate, nickel chloride hexahydrate, and cobalt chloride hexahydrate was changed to the feeding ratios shown in Table 1.

### Example 2-9

A nanowire was obtained by performing the same operation as in Example 2-2 except that sodium borohydride from which silicon had been removed to below the detection limit of the ICP-AES method by the recrystallization method was used.

### Example 2-10

In 300 parts by mass of water, 6.83 parts by mass (34.4 molar parts) of iron (II) chloride tetrahydrate and 2.05 parts by mass (8.6 molar parts) of nickel chloride hexahydrate were dissolved, and the solution was placed in a magnetic circuit opened to the atmosphere and having a central magnetic field of 130 mT (the molar ratio of iron (II) chloride tetrahydrate: nickel chloride hexahydrate was 80:20). Dropwise addition of an aqueous solution obtained by dissolving 7.00 parts by mass (185 molar parts) of sodium borohydride (containing 0.1 mass % of silicon) in 175 parts by mass of water was started without performing bubbling. The aqueous solution was added dropwise over 15 minutes, and then left to stand still for 10 minutes. The concentrations of the metal ions and the reducing agent in the reaction solution were as follows: (iron ion 45 mmol/L, nickel ion 45 mmol/L, reducing agent 389 mmol/L). A 20% aqueous sodium hydroxide solution was added to the obtained reaction solution to adjust the pH to 12 to 13, and the reaction solution was allowed to stand for 1 hour.

The application of the magnetic field was stopped, and the reaction solution was poured into 200 parts by mass of water to dilute. The generated black solid was collected by filtration using a PTFE filter “T100A090C”, washed three times with water and three times with methanol, and subjected to vacuum drying for 24 hours at room temperature to obtain a nanowire.

### Comparative Example 2-1

In 300 parts by mass of water, 10.2 parts by mass (43.0 molar parts) of nickel chloride hexahydrate was dissolved, and the solution was placed in a reaction vessel to which a magnetic field of 150 mT was applied. Bubbling of nitrogen gas was started immediately after the solution was charged. After a lapse of 10 minutes from the start of bubbling, dropwise addition of an aqueous solution obtained by dissolving 7.00 parts by mass (185 molar parts) of sodium borohydride in 175 parts by mass of water was started. The aqueous solution was added dropwise over 15 minutes, and then left to stand still for 10 minutes.

The application of the magnetic field and the nitrogen gas bubbling were stopped, and the reaction solution was poured into 200 parts by mass of water to dilute. The generated black solid was collected by filtration using a PTFE filter “T100A090C”, washed three times with water and three times with methanol, and subjected to vacuum drying for 24 hours at room temperature to obtain nanoparticles.

### Comparative Examples 2-2 and 2-3

Nanoparticles were obtained by performing the same operation as in Comparative Example 2-1 except that the feeding ratio of nickel chloride hexahydrate and cobalt chloride hexahydrate was changed to the feeding ratios shown in Table 1.

### Comparative Example 2-4

In a reaction vessel heated to 90 to 95° C., a solution prepared by dissolving 3.11 parts by mass (13.1 molar parts) of nickel chloride hexahydrate in 397 parts by mass of ethylene glycol and heating the solution to 90° C., a solution prepared by dissolving 1.00 parts by mass of sodium hydroxide in 472 parts by mass of ethylene glycol and heating the solution to 90° C., 25.0 parts by mass of 28% aqueous ammonia, a solution prepared by dissolving 0.75 parts by mass (3.78 molar parts) of iron (II) chloride tetrahydrate in 99.3 parts by mass of ethylene glycol, and 2.50 parts by mass of hydrazine monohydrate were added in this order. The addition of each liquid was performed at intervals of 10 seconds in the above order while stirring. After all of them were added, a magnetic field of 150 mT was applied, and a reduction reaction was performed for 90 minutes while maintaining 90 to 95° C.

After completion of the reaction, the generated black solid was collected by filtration using a PTFE filter “T100A090C”, washed three times with water and three times with methanol, and subjected to vacuum drying for 24 hours at room temperature to obtain a nanowire.

### Comparative Examples 2-5 to 2-7

The same operation as in Comparative Example 2-4 was performed except that the feeding ratio of iron (II) chloride tetrahydrate, nickel chloride hexahydrate, and cobalt chloride hexahydrate was changed to the feeding ratios shown in Table 1. However, the reduction reaction did not proceed, and no product was obtained.

### Comparative Example 2-8

A nanowire was obtained by performing the same operation as in Comparative Example 2-1 except that the feeding ratio of iron (II) chloride tetrahydrate and nickel chloride hexahydrate was changed to the feeding ratio shown in Table 1, and nitrogen bubbling was not performed.

The evaluation results of the products obtained in Examples and Comparative Examples of Experimental Example 2 are shown in Table 2.

TABLE 2
Experimental Example 2 (Second embodiment)

| | | | | Production conditions | | | | Nanowire | | | | Constituent ratio | | | | | | | | | | | | Magnetic properties | | | |
|---|---|---|---|---|---|---|---|---|---|---|---|---|---|---|---|---|---|---|---|---|---|---|---|---|---|---|---|
| | | | | | Amount | | | | Aver- | | | (mol %) by | | | | | Constituent ratio | | | | | | | Satur- | Relative | | |
| | Feeding ratio | | | | of dis- | | Nano- | Aver- | age | | | SEM-EDS (1) | | | | | (mass ratio) | | | | | | Total | ation | magnetic | | Over- |
| | (molar ratio) | | | Re- | solved | Basic | wire | age | dia- | As- | | | | | | Fe/B | by ICP-AES (2) | | | | | | a- | magne- | perme- | Coer- | all |
| | X | Y | Z | ducing | oxygen | treat- | forma- | length | meter | pect | Crystal- | | | | | (molar | | | | | | Fe + | mount | tization | ability | civity | eval- |
| | (Fe) | (Ni) | (Co) | agent | (mg/L) | ment | tion | μm | nm | ratio | linity | Fe | Ni | Co | B | ratio) | Fe | Ni | Co | B | Si | Co | (3) | emu/g | — | Oe | uation |
| Ex- | 50 | 50 | 0 | NaBH₄ | 2 | None | ◯ | 10⊚ | 100 | 100 | ◯ | 31 | 29 | 0 | 40 | 0.8⊚⊚ | 45.0 | 47.0 | 0 | 7.8 | 0.2 | 45.0 | 89.5 | 56.5◯ | 5Δ | 355⊚ | Δ |
| ample | | | | | | | | | | | | | | | | | | | | | | | | | | | |
| 2-1 | | | | | | | | | | | | | | | | | | | | | | | | | | | |
| Ex- | 80 | 20 | 0 | NaBH₄ | 2 | None | ◯ | 12⊚ | 95 | 126 | ◯ | 46 | 13 | 0 | 41 | 1.1⊚⊚ | 73.8 | 18.0 | 0 | 8.1 | 0.1 | 73.8 | 85.9 | 79.0⊚ | 48⊚ | 369⊚ | ⊚ |
| ample | | | | | | | | | | | | | | | | | | | | | | | | | | | |
| 2-2 | | | | | | | | | | | | | | | | | | | | | | | | | | | |
| Ex- | 90 | 10 | 0 | NaBH₄ | 2 | None | ◯ | 10⊚ | 85 | 118 | ◯ | 56 | 6 | 0 | 38 | 1.5⊚⊚ | 85.6 | 7.0 | 0 | 7.3 | 0.1 | 85.6 | 73.0 | 72.0⊚ | 52⊚ | 340⊚ | ⊚ |
| ample | | | | | | | | | | | | | | | | | | | | | | | | | | | |
| 2-3 | | | | | | | | | | | | | | | | | | | | | | | | | | | |
| Ex- | 50 | 0 | 50 | NaBH₄ | 2 | None | ◯ | 12⊚ | 110 | 109 | ◯ | 29 | 0 | 34 | 37 | 0.8⊚⊚ | 46.0 | 0 | 47.0 | 6.5 | 0.5 | 93.0 | 94.7 | 104.4⊚ | 16◯ | 330⊚ | ◯ |
| ample | | | | | | | | | | | | | | | | | | | | | | | | | | | |
| 2-4 | | | | | | | | | | | | | | | | | | | | | | | | | | | |
| Ex- | 80 | 0 | 20 | NaBH₄ | 2 | None | ◯ | 13⊚ | 100 | 130 | ◯ | 48 | 0 | 12 | 40 | 1.2⊚⊚ | 64.8 | 0 | 29.0 | 6.1 | 0.1 | 93.8 | 79.8 | 74.9⊚ | 13◯ | 496◯ | ◯ |
| ample | | | | | | | | | | | | | | | | | | | | | | | | | | | |
| 2-5 | | | | | | | | | | | | | | | | | | | | | | | | | | | |
| Ex- | 60 | 20 | 20 | NaBH₄ | 2 | None | ◯ | 10⊚ | 100 | 100 | ◯ | 43 | 12 | 14 | 31 | 1.4⊚⊚ | 53.0 | 19.0 | 20.0 | 7.8 | 0.2 | 73.0 | 75.5 | 47.4◯ | 5Δ | 213⊚ | Δ |
| ample | | | | | | | | | | | | | | | | | | | | | | | | | | | |
| 2-6 | | | | | | | | | | | | | | | | | | | | | | | | | | | |
| Ex- | 60 | 10 | 30 | NaBH₄ | 2 | None | ◯ | 10⊚ | 95 | 105 | ◯ | 39 | 6 | 21 | 33 | 1.2⊚⊚ | 54.0 | 9.0 | 29.0 | 7.8 | 0.2 | 83.0 | 70.3 | 51.8◯ | 6Δ | 410◯ | Δ |
| ample | | | | | | | | | | | | | | | | | | | | | | | | | | | |
| 2-7 | | | | | | | | | | | | | | | | | | | | | | | | | | | |
| Ex- | 80 | 10 | 10 | NaBH₄ | 2 | None | ◯ | 12⊚ | 100 | 120 | ◯ | 54 | 6 | 7 | 33 | 1.6⊚⊚ | 73.0 | 10.0 | 10.0 | 6.8 | 0.2 | 83.0 | 76.6 | 47.8◯ | 31◯ | 321⊚ | ◯ |
| ample | | | | | | | | | | | | | | | | | | | | | | | | | | | |
| 2-8 | | | | | | | | | | | | | | | | | | | | | | | | | | | |
| Ex- | 80 | 20 | 0 | NaBH₄ | 2 | None | ◯ | 10⊚ | 100 | 100 | ◯ | 53 | 14 | 0 | 34 | 1.6⊚⊚ | 72.1 | 19.0 | 0 | 8.9 | 0 | 72.1 | 67.4 | 41.4◯ | 10◯ | 402◯ | ◯ |
| ample | | | | | | | | | | | | | | | | | | | | | | | | | | | |
| 2-9 | | | | | | | | | | | | | | | | | | | | | | | | | | | |
| Ex- | 80 | 20 | 0 | NaBH₄ | 7 | Per- | ◯ | 11⊚ | 100 | 110 | ◯ | 57 | 18 | 0 | 25 | 2.3⊚⊚ | 74.7 | 18.4 | 0 | 6.7 | 0.1 | 74.7 | 81.5 | 62.8⊚ | 42⊚ | 175⊚⊚ | ⊚ |
| ample | | | | | | formed | | | | | | | | | | | | | | | | | | | | | |
| 2-10 | | | | | | | | | | | | | | | | | | | | | | | | | | | |
| Com- | 0 | 100 | 0 | NaBH₄ | 2 | None | X | — | 47 | — | — | 0 | 65 | 0 | 35 | 0 | 0 | 90.9 | 0 | 9.0 | 0.1 | 0 | 99.0 | 0.2X | 1X | 77⊚ | X |
| parative | | | | | | | | | | | | | | | | | | | | | | | | | | | |
| Ex- | | | | | | | | | | | | | | | | | | | | | | | | | | | |
| ample | | | | | | | | | | | | | | | | | | | | | | | | | | | |
| 2-1 | | | | | | | | | | | | | | | | | | | | | | | | | | | |
| Com- | 0 | 0 | 100 | NaBH₄ | 2 | None | X | — | 55 | — | — | 0 | 0 | 65 | 35 | 0 | 0 | 0 | 90.9 | 9.0 | 0.1 | 90.9 | 96.9 | 0.3X | 2X | 76⊚ | X |
| parative | | | | | | | | | | | | | | | | | | | | | | | | | | | |
| Ex- | | | | | | | | | | | | | | | | | | | | | | | | | | | |
| ample | | | | | | | | | | | | | | | | | | | | | | | | | | | |
| 2-2 | | | | | | | | | | | | | | | | | | | | | | | | | | | |
| Com- | 0 | 50 | 50 | NaBH₄ | 2 | None | X | — | 53 | — | — | 0 | 36 | 35 | 29 | 0 | 0 | 47.9 | 45.0 | 7.0 | 0.1 | 45.0 | 98.2 | 0.3X | 1X | 80⊚ | X |
| parative | | | | | | | | | | | | | | | | | | | | | | | | | | | |
| Ex- | | | | | | | | | | | | | | | | | | | | | | | | | | | |
| ample | | | | | | | | | | | | | | | | | | | | | | | | | | | |
| 2-3 | | | | | | | | | | | | | | | | | | | | | | | | | | | |
| Com- | 20 | 80 | 0 | N₂H₄ | 2 | None | ◯ | 11⊚ | 90 | 122 | X | 23 | 77 | 0 | 0 | — | 22.0 | 78.0 | 0 | 0 | 0 | 22.0 | 88.0 | 62.0⊚ | 31◯ | 610X | X |
| parative | | | | | | | | | | | | | | | | | | | | | | | | | | | |
| Ex- | | | | | | | | | | | | | | | | | | | | | | | | | | | |
| ample | | | | | | | | | | | | | | | | | | | | | | | | | | | |
| 2-4 | | | | | | | | | | | | | | | | | | | | | | | | | | | |
| Com- | 80 | 20 | 0 | N₂H₄ | 2 | None | XX | — | — | — | — | — | — | — | — | — | — | — | — | — | — | — | — | — | — | — | X |
| parative | | | | | | | | | | | | | | | | | | | | | | | | | | | |
| Ex- | | | | | | | | | | | | | | | | | | | | | | | | | | | |
| ample | | | | | | | | | | | | | | | | | | | | | | | | | | | |
| 2-5 | | | | | | | | | | | | | | | | | | | | | | | | | | | |
| Com- | 80 | 0 | 20 | N₂H₄ | 2 | None | XX | — | — | — | — | — | — | — | — | — | — | — | — | — | — | — | — | — | — | — | X |
| parative | | | | | | | | | | | | | | | | | | | | | | | | | | | |
| Ex- | | | | | | | | | | | | | | | | | | | | | | | | | | | |
| ample | | | | | | | | | | | | | | | | | | | | | | | | | | | |
| 2-6 | | | | | | | | | | | | | | | | | | | | | | | | | | | |
| Com- | 80 | 10 | 10 | N₂H₄ | 2 | None | XX | — | — | — | — | — | — | — | — | — | — | — | — | — | — | — | — | — | — | — | X |
| parative | | | | | | | | | | | | | | | | | | | | | | | | | | | |
| Ex- | | | | | | | | | | | | | | | | | | | | | | | | | | | |
| ample | | | | | | | | | | | | | | | | | | | | | | | | | | | |
| 2-7 | | | | | | | | | | | | | | | | | | | | | | | | | | | |
| Com- | 100 | 0 | 0 | NaBH₄ | 7 | None | ◯ | 4X | 60 | 67 | X | 82 | 0 | 0 | 18 | 4.6◯ | 95.3 | 0 | 0 | 4.6 | 0.1 | 95.3 | 72.4 | 38X | 6Δ | 255⊚ | X |
| parative | | | | | | | | | | | | | | | | | | | | | | | | | | | |
| Ex- | | | | | | | | | | | | | | | | | | | | | | | | | | | |
| ample | | | | | | | | | | | | | | | | | | | | | | | | | | | |
| 2-8 | | | | | | | | | | | | | | | | | | | | | | | | | | | |

X iron (II) chloride tetrahydrate,
Y nickel chloride hexahydrate,
Z cobalt chloride hexahydrate,
(1) Molar ratio of Fe, Ni, Co, and B (mol %),
(2) Proportion of Fe, Ni, Co, B, and Si to total content X (mass ratio),
(3) Proportion of total content X of Fe, Ni, Co, B and Si in nanowire (proportion with respect to entire nanowire) (mass %)

The nanowires of Examples 2-1 to 2-10, containing iron, cobalt and/or nickel, and boron and having an average length of 5 μm or more, had a saturation magnetization of 40 emu/g or more, a relative magnetic permeability of 5 or more, and a coercivity of less than 500 Oe.

From the comparison of the nanowires of Examples 2-2 and 2-9, it is found that an increase in coercivity is suppressed and the saturation magnetization and the relative magnetic permeability are significantly increased by containing silicon.

In Comparative Examples 2-1 to 2-3, since iron was not contained, a nanowire was not formed, and the obtained particles had low saturation magnetization and relative magnetic permeability.

In the nanowire of Comparative Example 2-4, since boron was not contained, a crystalline peak was observed as shown in FIG. 2, and the coercivity was high.

In Comparative Examples 2-5 to 2-7, since boron was not contained, the reduction reaction did not proceed, and no product was obtained.

In the nanowire of Comparative Example 2-8, since cobalt and/or nickel were not contained, the nanowire length was short, a crystalline peak was observed, and the saturation magnetization was low.

### Experimental Example 3 (third embodiment)

### A. Various Evaluations

### (1) Qualitative and Quantitative Determination of Metal Species of Nanowire

The obtained product was subjected to vacuum drying and then dissolved in a mixed solution of dilute hydrochloric acid and dilute nitric acid. The obtained solution was subjected to ICP-AES method, and the contents of Fe, Ni, Ag, and B were quantified by a calibration curve method using Fe, Ni, Ag, and B standard solutions.

The total content other than Fe, Ni, Ag, and B in the nanowire was determined by subtracting the content of Fe, Ni, Ag, and B from the mass of the nanowire.

### (2) Average Length and Average Diameter of Nanowires

The average length and average diameter of the nanowires were measured in the same manner as in the method for evaluating nanowire formation in Experimental Example 1, and the aspect ratio was calculated.

### (3) Electromagnetic Wave Absorption (I) of Millimeter Wave

The electromagnetic wave absorption (reflection attenuation amount) of the produced electromagnetic wave absorber having a thickness of 100 μm was evaluated by a free space method. The (average) absorption amount of 26.5 GHz to 40 GHz used for 5G wireless communication was evaluated according to the following criteria.
⊙: 15 dB or more (best);
◯: 10 dB or more and less than 15 dB (excellent);
Δ: 5 dB or more and less than 10 dB (having no problem in practical use);
X: less than 5 dB (having a problem in practical use)

### (4) Electromagnetic Wave Absorption (II) of Millimeter Wave

The electromagnetic wave absorption (reflection attenuation amount) of the produced electromagnetic wave absorber having a thickness of 100 μm was evaluated by a free space method. The (average) absorption amount of 74 GHz to 81 GHz used for 5G wireless communication was evaluated according to the following criteria.
⊙: 15 dB or more (best);
◯: 10 dB or more and less than 15 dB (excellent);
Δ: 5 dB or more and less than 10 dB (having no problem in practical use);
X: less than 5 dB (having a problem in practical use)

### (5) Overall Evaluation

Of the evaluation results of the electromagnetic wave absorption (I) and the electromagnetic wave absorption (II) of millimeter waves, better evaluation results were used as comprehensive evaluation.

### (6) Aspects A-C

Examples of Experimental Example 3 were classified into Aspects A to C described above. Example 3-3 is positioned as an example not classified into any of Aspects A to C.

### B. Raw Materials

### B-1. Nanowire or Particle

### (1) FeBNW

In 300 parts by mass of water, 8.55 parts by mass (43 molar parts) of iron (II) chloride tetrahydrate was dissolved, the solution was placed in a magnetic circuit having a central magnetic field of 130 mT, and nitrogen gas bubbling was started. After a lapse of 10 minutes from the start of bubbling, dropwise addition of an aqueous solution obtained by dissolving 7.00 parts by mass (185 molar parts) of sodium borohydride in 175 parts by mass of water was started. The aqueous solution was added dropwise over 15 minutes, and then left to stand still for 10 minutes.

Thereafter, the application of the magnetic field and the nitrogen gas bubbling were stopped, and the reaction solution was poured into 200 parts by mass of water to dilute. The generated black nanowire was collected by filtration using a PTFE filter T100A090C, washed three times with water and three times with methanol, and subjected to vacuum drying for 24 hours at room temperature to obtain a nanowire.

### (2) Fe90Ni10BNW

In 1556.22 parts by mass of water, 29.3 parts by mass (147 molar parts) of iron (II) chloride tetrahydrate and 3.9 parts by mass (16.4 molar parts) of nickel chloride hexahydrate were dissolved, the resulted solution was placed in a magnetic circuit having a central magnetic field of 130 mT (molar ratio of iron (II) chloride tetrahydrate: nickel chloride was 90:10), and nitrogen gas bubbling was started. After a lapse of 10 minutes from the start of bubbling, dropwise addition of an aqueous solution obtained by dissolving 12.4 parts by mass (327 molar parts) of sodium borohydride in 310 parts by mass of water was started. The aqueous solution was dropped over 15 minutes, and then left to stand still for 10 minutes.

The application of the magnetic field and the nitrogen gas bubbling were stopped, and the reaction solution was poured into 200 parts by mass of water to dilute. The generated black solid was collected by filtration using a PTFE filter T100A090C, washed three times with water and three times with methanol, and subjected to vacuum drying for 24 hours at room temperature to obtain a nanowire.

### (3) Fe80Ni20BNW

In 1556.22 parts by mass of water, 26.0 parts by mass (131 molar parts) of iron (II) chloride tetrahydrate and 7.78 parts by mass (32.7 molar parts) of nickel chloride hexahydrate were dissolved, the resulted solution was placed in a magnetic circuit having a central magnetic field of 130 mT (molar ratio of iron (II) chloride tetrahydrate: nickel chloride was 80:20), and nitrogen gas bubbling was started. After a lapse of 10 minutes from the start of bubbling, dropwise addition of an aqueous solution obtained by dissolving 12.4 parts by mass (327 molar parts) of sodium borohydride in 310 parts by mass of water was started. The aqueous solution was added dropwise over 15 minutes, and then left to stand still for 10 minutes.

The application of the magnetic field and the nitrogen gas bubbling were stopped, and the reaction solution was poured into 200 parts by mass of water to dilute. The generated black solid was collected by filtration using a PTFE filter T100A090C, washed three times with water and three times with methanol, and subjected to vacuum drying for 24 hours at room temperature to obtain a nanowire.

### (4) Fe70Ni30BNW

In 1556.22 parts by mass of water, 22.8 parts by mass (114.7 molar parts) of iron (II) chloride tetrahydrate and 11.7 parts by mass (49.1 molar parts) of nickel chloride hexahydrate were dissolved, the solution was placed in a magnetic circuit having a central magnetic field of 130 mT (molar ratio of iron (II) chloride tetrahydrate:nickel chloride was 70:30), and nitrogen gas bubbling was started. After a lapse of 10 minutes from the start of bubbling, dropwise addition of an aqueous solution obtained by dissolving 12.4 parts by mass (327 molar parts) of sodium borohydride in 310 parts by mass of water was started. The aqueous solution was added dropwise over 15 minutes, and then left to stand still for 10 minutes.

The application of the magnetic field and the nitrogen gas bubbling were stopped, and the reaction solution was poured into 200 parts by mass of water to dilute. The generated black solid was collected by filtration using a PTFE filter T100A090C, washed three times with water and three times with methanol, and subjected to vacuum drying for 24 hours at room temperature to obtain a nanowire.

### (5) Fe65Ni35NW

Nickel chloride hexahydrate in an amount of 6.89 parts by mass (28.99 molar parts) and 0.30 parts by mass (1.02 molar parts) of trisodium citrate dihydrate were dissolved in ethylene glycol to obtain a total amount of 350.0 parts by mass. This solution was heated to 90° C. to dissolve nickel chloride, thereby obtaining a nickel-citrate solution.

Sodium hydroxide in an amount of 2.50 parts by mass (62.52 molar parts) was dissolved in ethylene glycol to obtain the total amount of 388.5 parts by mass. This solution was heated to 90° C. to dissolve sodium hydroxide, thereby obtaining a sodium hydroxide solution.

Iron (II) chloride tetrahydrate in an amount of 10.78 parts by mass (54.17 molar parts) was dissolved in ethylene glycol to obtain a total amount of 150.0 parts by mass. Iron (II) chloride tetrahydrate was dissolved by stirring at room temperature, whereby an iron solution was obtained.

A reaction vessel in a magnetic circuit capable of applying a magnetic field at the center was heated to 90 to 95° C., and 350.0 parts by mass of the nickel-citrate solution, 388.5 parts by mass of the sodium hydroxide solution, 100.0 parts by mass of 28% aqueous ammonia (ammonia amount: 28.0 g), 150.0 parts by mass of the iron solution, and 11.5 parts by mass of hydrazine monohydrate (229.72 molar parts) were added in this order. After all of them were added, a magnetic field of 150 mT was applied, and a reduction reaction was performed for 90 minutes at 90 to 95° C.

After completion of the reaction, a nanowire was recovered using a PTFE filter T100A090C.

### (6) NiNW

Nickel chloride hexahydrate in an amount of 10.0 parts by mass (42.1 molar parts) and 0.935 parts by mass (3.18 molar parts) of trisodium citrate dihydrate were dissolved in ethylene glycol to be prepared in 500 parts by mass.

Sodium hydroxide in an amount of 2.50 parts by mass (62.5 molar parts) was dissolved in ethylene glycol to be prepared in 442 parts by mass.

The two liquids were mixed and put into a magnetic circuit having a central magnetic field of 130 mT, 55.0 parts by mass (904 molar parts) of 28% aqueous ammonia and 2.50 parts by mass (49.9 molar parts) of hydrazine monohydrate were added in this order, and the obtained mixture was heated at 90 to 95° C. for 15 minutes.

Thereafter, the application of the magnetic field was stopped, and the generated black solid was collected by filtration using a PTFE filter T100A090C, washed three times with water and three times with methanol, and vacuum-dried for 24 hours to obtain a nanowire.

### (7) AgNW

A Ag nanowire was filtered and collected from a Ag nanowire dispersion manufactured by Sigma-Aldrich using a PTFE filter T100A090C, then washed three times with water and three times methanol, and vacuum-dried for 24 hours to obtain a nanowire.

### (8) NiP

Ni particles manufactured by Sigma-Aldrich Co., Ltd. (diameter: 1 μm or less)

### (9) FeBNW-Na

In 300 parts by mass of water, 8.55 parts by mass (43 molar parts) of iron (II) chloride tetrahydrate was dissolved, the solution was placed in a magnetic circuit having a central magnetic field of 130 mT, and an aqueous solution obtained by dissolving 7.00 parts by mass (185 parts by mol) of sodium borohydride in 175 parts by mass of water was added dropwise over 15 minutes without performing bubbling.

Thereafter, the application of the magnetic field was stopped, and the reaction solution was poured into 200 parts by mass of an aqueous sodium hydroxide solution and diluted to adjust the pH to about 12. After a lapse of 1 hour, the generated black nanowire was collected by filtration using a PTFE filter T100A090C, washed three times with water and three times with methanol, and subjected to vacuum drying for 24 hours at room temperature to obtain a nanowire.

“FeBNW-Na” means FeBNW subjected to surface treatment with an aqueous sodium hydroxide solution.

### (10) Fe80Ni20BNW-Na

In 1556.22 parts by mass of water, 26.0 parts by mass (131 molar parts) of iron (II) chloride tetrahydrate and 7.78 parts by mass (32.7 molar parts) of nickel chloride hexahydrate were dissolved, the solution was placed in a magnetic circuit having a central magnetic field of 130 mT (molar ratio of iron (II) chloride tetrahydrate:nickel chloride was 80:20), and an aqueous solution obtained by dissolving 12.4 parts by mass (327 molar parts) of sodium borohydride in 310 parts by mass of water was added dropwise over 15 minutes without performing bubbling.

The application of the magnetic field was stopped, and the reaction solution was poured into 200 parts by mass of an aqueous sodium hydroxide solution and diluted to adjust the pH to about 12. After a lapse of 1 hour, the generated black solid was collected by filtration using a PTFE filter T100A090C, washed three times with water and three times with methanol, and subjected to vacuum drying for 24 hours at room temperature to obtain a nanowire.

“Fe80Ni20BNW-Na” means Fe80Ni20BNW subjected to surface treatment with an aqueous sodium hydroxide solution.

The characteristic values of the nanowires and particles used are shown in Table 3.

TABLE 3
Experimental Example 3 (third embodiment)

| | Nanowire (1) | | | | | | | |
|---|---|---|---|---|---|---|---|---|
| | | | | | Total content | | | Average |
| | | | | | other than | Average | Average | length/ |
| | | | | | Fe, Ni, Ag, and | length | diameter | average |
| | Fe | Ni | Ag | B | B (mass %) | μm | nm | diameter |
| FeBNW | 94.8 | 0.0 | 0.0 | 5.2 | 0.0 | 12 | 70 | 171 |
| Fe90Ni10BNW | 86.0 | 7.0 | 0.0 | 7.3 | 27.0 | 10 | 85 | 118 |
| Fe80Ni20BNW | 73.9 | 18.0 | 0.0 | 8.1 | 14.1 | 12 | 95 | 126 |
| Fe70Ni30BNW | 65.6 | 28.1 | 0.0 | 6.3 | 15.9 | 19 | 98 | 194 |
| Fe65Ni35NW | 64.0 | 36.0 | 0.0 | 0.0 | 15.4 | 23 | 200 | 116 |
| NiNW | 0.0 | 100.0 | 0.0 | 0.0 | 8.0 | 24 | 100 | 240 |
| AgNW | 0.0 | 0.0 | 100.0 | 0.0 | 7.3 | 21 | 115 | 183 |
| NiP | 0.0 | 100.0 | 0.0 | 0.0 | 0.0 | 0.8 | 800 | 1 |
| FeBNW-Na | 94.8 | 0.0 | 0.0 | 5.2 | 0.0 | 12 | 70 | 171 |
| Fe80Ni20BNW-Na | 73.9 | 18.0 | 0.0 | 8.1 | 14.1 | 12 | 95 | 126 |

(1) Content with respect to total content of iron, nickel and boron.

### B-2. Binder

### (1) Silicone Resin

Resin mixed at TSE3450 manufactured by Momentive Performance Materials Inc./TSE3450 manufactured by Momentive Performance Materials Inc.=10/1 (mass ratio)

### (2) Epoxy Resin

Resin mixed at Nisshin Resin Z-1/Nisshin Resin Curing Agent 50 minutes type=100/20 (mass ratio)

### (3) Acrylic Resin

Resin mixed at EPOCH SS101/EPOCH NYPER E=100/0.2 (mass ratio)

### Example 3-1

FeBNW in an amount of 80 mass % and 20 mass % of a silicone resin were mixed and molded with a tabletop hand press machine (RC-2000 manufactured by NODA CO., LTD.) to prepare a sheet of 12 cm×12 cm×100 μm in thickness.

### Examples 3-2 to 3-22, Comparative Examples 3-2 to 3-8, and Reference Example 3-1

A sheet was prepared by the same procedure as in Example 3-1 except that the type and ratio of the nanowire or the particle and the binder were changed to the conditions shown in Table 2.

### Comparative Example 3-1

FeBNW in an amount of 45 mass %, 5 mass % of a silicone resin, and 50 mass % of toluene were mixed, poured into a mold, and dried at 100° C. to prepare a sheet of 12 cm×12 cm×100 μm in thickness.

### Reference Example 3-2

A sheet was prepared in the same manner as in Reference Example 3-1 except that the thickness was changed to 600 nm.

The configuration and evaluation of the obtained sheets are shown in Table 4.

TABLE 4
Experimental Example 3 (third embodiment)

| | | | | | | | Electromagnetic | | | | Electromagnetic | | | | |
|---|---|---|---|---|---|---|---|---|---|---|---|---|---|---|---|
| | | | | | | | wave absorption I | | | | wave absorption II | | | | |
| | | Nanowire or particle | | Binder | | Thick- | ( 26.5 GHz to 40 GHz) | | | | (74 GHz to 81 GHz) | | | | |
| | | | Con- | | Con- | ness | Maxi- | Mini- | | | Maxi- | Mini- | | | |
| | | | tent | | tent | of | mum | mum | Aver- | | mum | mum | Aver- | | Overall |
| | As- | | (mass | | (mass | sheet | value | value | age | Eval- | value | value | age | Eval- | Eval- |
| | pects | Type | %) | Type | %) | (μm) | (dB) | (dB) | value | uation | (dB) | (dB) | value | uation | uation |
| Example | B | FeBNW | 80 | Silicone | 20 | 100 | 6 | 2 | 3 | X | 25 | 10 | 18 | ⊚ | ⊚ |
| 3-1 | | | | resin | | | | | | | | | | | |
| Example | B | FeBNW | 50 | Silicone | 50 | 100 | 6 | 2 | 3 | X | 25 | 7 | 16 | ⊚ | ⊚ |
| 3-2 | | | | resin | | | | | | | | | | | |
| Example | — | FeBNW | 30 | Silicone | 70 | 100 | 23 | 3 | 8 | Δ | 5 | 5 | 5 | Δ | Δ |
| 3-3 | | | | resin | | | | | | | | | | | |
| Example | B | Fe90Ni10BNW | 80 | Silicone | 20 | 100 | 8 | 3 | 4 | X | 26 | 12 | 19 | ⊚ | ⊚ |
| 3-4 | | | | resin | | | | | | | | | | | |
| Example | B | Fe90Ni10BNW | 50 | Silicone | 50 | 100 | 7 | 3 | 4 | X | 23 | 8 | 17 | ⊚ | ⊚ |
| 3-5 | | | | resin | | | | | | | | | | | |
| Example | A | Fe80Ni20BNW | 80 | Silicone | 20 | 100 | 31 | 12 | 19 | ⊚ | 10 | 4 | 6 | Δ | ⊚ |
| 3-6 | | | | resin | | | | | | | | | | | |
| Example | A | Fe80Ni20BNW | 50 | Silicone | 50 | 100 | 23 | 13 | 17 | ⊚ | 8 | 5 | 6 | Δ | ⊚ |
| 3-7 | | | | resin | | | | | | | | | | | |
| Example | C | Fe80Ni20BNW | 40 | Silicone | 60 | 100 | 7 | 2 | 5 | Δ | 20 | 16 | 18 | ⊚ | ⊚ |
| 3-8 | | | | resin | | | | | | | | | | | |
| Example | C | Fe80Ni20BNW | 30 | Silicone | 70 | 100 | 7 | 3 | 5 | Δ | 18 | 14 | 16 | ⊚ | ⊚ |
| 3-9 | | | | resin | | | | | | | | | | | |
| Example | A | Fe70Ni30BNW | 80 | Silicone | 20 | 100 | 22 | 15 | 17 | ⊚ | 8 | 7 | 7 | Δ | ⊚ |
| 3-10 | | | | resin | | | | | | | | | | | |
| Example | A | Fe70Ni30BNW | 50 | Silicone | 50 | 100 | 17 | 14 | 16 | ⊚ | 6 | 4 | 5 | Δ | ⊚ |
| 3-11 | | | | resin | | | | | | | | | | | |
| Example | C | Fe70Ni30BNW | 40 | Silicone | 60 | 100 | 8 | 5 | 6 | Δ | 18 | 14 | 15 | ⊚ | ⊚ |
| 3-12 | | | | resin | | | | | | | | | | | |
| Example | C | Fe70Ni30BNW | 30 | Silicone | 70 | 100 | 6 | 4 | 5 | Δ | 17 | 13 | 15 | ⊚ | ⊚ |
| 3-13 | | | | resin | | | | | | | | | | | |
| Example | B | FeBNW | 50 | Epoxy | 50 | 100 | 5 | 1 | 3 | X | 28 | 8 | 18 | ⊚ | ⊚ |
| 3-14 | | | | resin | | | | | | | | | | | |
| Example | B | FeBNW | 50 | Acrylic | 50 | 100 | 6 | 2 | 3 | X | 26 | 9 | 15 | ⊚ | ⊚ |
| 3-15 | | | | resin | | | | | | | | | | | |
| Example | A | Fe80Ni20BNW | 50 | Epoxy | 50 | 100 | 25 | 14 | 16 | ⊚ | 8 | 4 | 6 | Δ | ⊚ |
| 3-16 | | | | resin | | | | | | | | | | | |
| Example | A | Fe80Ni20BNW | 50 | Acrylic | 50 | 100 | 23 | 14 | 17 | ⊚ | 7 | 5 | 6 | Δ | ⊚ |
| 3-17 | | | | resin | | | | | | | | | | | |
| Example | C | Fe80Ni20BNW | 30 | Epoxy | 70 | 100 | 8 | 3 | 6 | Δ | 20 | 13 | 17 | ⊚ | ⊚ |
| 3-18 | | | | resin | | | | | | | | | | | |
| Example | C | Fe80Ni20BNW | 30 | Acrylic | 70 | 100 | 7 | 2 | 4 | X | 19 | 14 | 16 | ⊚ | ⊚ |
| 3-19 | | | | resin | | | | | | | | | | | |
| Example | A | Fe80Ni20BNW- | 50 | Silicone | 50 | 100 | 22 | 13 | 17 | ⊚ | 10 | 5 | 7 | Δ | ⊚ |
| 3-20 | | Na | | resin | | | | | | | | | | | |
| Example | B | FeBNW-Na | 50 | Silicone | 50 | 100 | 6 | 3 | 4 | X | 28 | 7 | 17 | ⊚ | ⊚ |
| 3-21 | | | | resin | | | | | | | | | | | |
| Example | C | Fe80Ni20BNW- | 30 | Silicone | 70 | 100 | 7 | 3 | 6 | Δ | 19 | 14 | 16 | ⊚ | ⊚ |
| 3-22 | | Na | | resin | | | | | | | | | | | |
| Com- | — | FeBNW | 90 | Silicone | 10 | 100 | 7 | 2 | 4 | X | 8 | 2 | 4 | X | X |
| parative | | | | resin | | | | | | | | | | | |
| Example | | | | | | | | | | | | | | | |
| 3-1 | | | | | | | | | | | | | | | |
| Com- | — | NiNW | 50 | Silicone | 50 | 100 | 4 | 3 | 3 | X | 4 | 3 | 4 | X | X |
| parative | | | | resin | | | | | | | | | | | |
| Example | | | | | | | | | | | | | | | |
| 3-2 | | | | | | | | | | | | | | | |
| Com- | — | NiNW | 30 | Silicone | 70 | 100 | 4 | 3 | 3 | X | 5 | 3 | 4 | X | X |
| parative | | | | resin | | | | | | | | | | | |
| Example | | | | | | | | | | | | | | | |
| 3-3 | | | | | | | | | | | | | | | |
| Com- | — | AgNW | 50 | Silicone | 50 | 100 | 5 | 2 | 4 | X | 4 | 3 | 4 | X | X |
| parative | | | | resin | | | | | | | | | | | |
| Example | | | | | | | | | | | | | | | |
| 3-4 | | | | | | | | | | | | | | | |
| Com- | — | AgNW | 30 | Silicone | 70 | 100 | 7 | 3 | 4 | X | 8 | 3 | 4 | X | X |
| parative | | | | resin | | | | | | | | | | | |
| Example | | | | | | | | | | | | | | | |
| 3-5 | | | | | | | | | | | | | | | |
| Com- | — | NiP | 50 | Silicone | 50 | 100 | 1 | 0.2 | 0.5 | X | 2 | 0.4 | 0.7 | X | X |
| parative | | | | resin | | | | | | | | | | | |
| Example | | | | | | | | | | | | | | | |
| 3-6 | | | | | | | | | | | | | | | |
| Com- | — | NiP | 30 | Silicone | 70 | 100 | 2 | 0.3 | 1 | X | 3 | 0.5 | 0.7 | X | X |
| parative | | | | resin | | | | | | | | | | | |
| Example | | | | | | | | | | | | | | | |
| 3-7 | | | | | | | | | | | | | | | |
| Com- | — | Fe65Ni35NW | 50 | Silicone | 70 | 100 | 4 | 0.6 | 1 | X | 5 | 0.7 | 2 | X | X |
| parative | | | | resin | | | | | | | | | | | |
| Example | | | | | | | | | | | | | | | |
| 3-8 | | | | | | | | | | | | | | | |
| Refer- | — | NiNW | 30 | Silicone | 70 | 1000 | 6 | 0.9 | 2 | X | 21 | 17 | 19 | ⊚ | ⊚ |
| ence | | | | resin | | | | | | | | | | | |
| Example | | | | | | | | | | | | | | | |
| 3-1 | | | | | | | | | | | | | | | |
| Refer- | — | NiNW | 30 | Silicone | 70 | 600 | 7 | 0.4 | 2 | X | 8 | 0.8 | 4 | X | X |
| ence | | | | resin | | | | | | | | | | | |
| Example | | | | | | | | | | | | | | | |
| 3-2 | | | | | | | | | | | | | | | |

The sheets of Examples 3-1 to 3-22, in which the nanowire contained boron and iron, the content of iron in the nanowire was 65 mass % or more, and the content of the nanowire was 85 mass % or less (particularly 25 to 85 mass %) with respect to the total of the nanowire and the binder, had electromagnetic wave absorption of 5 dB or more in at least one of the band of 26.5 to 40 GHz used for 5G wireless communication and the band of 74 to 81 GHz used for a millimeter wave radar, even with a small thickness.

In the sheets of Examples 3-6 to 3-7, 3-10 to 3-11, 3-16 to 3-17, and 3-20, the nanowire contained boron and iron, the content of iron in the nanowire was 65 mass % or more and less than 80 mass %, and the content of the nanowire was 45 to 85 mass % with respect to the total of the nanowire and the binder. Thus, the sheets had electromagnetic wave absorption of 15 dB or more in the band of 26.5 to 40 GHz used for 5G wireless communication even with a small thickness.

In the sheets of Examples 3-1 to 3-2, 3-4 to 3-5, 3-14 to 3-15, and 3-21, the nanowire contained boron and iron, the content of iron in the nanowire was 80 to 95 mass %, and the content of the nanowire was 45 to 85 mass % with respect to the total of the nanowire and the binder. Thus, the sheets had electromagnetic wave absorption of 15 dB or more in the band of 74 to 81 GHz used for a millimeter wave radar even with a small thickness.

In the sheets of Examples 3-8 to 3-9, 3-12 to 3-13, 3-18 to 3-19, and 3-22, the nanowire contained boron and iron, the content of iron in the nanowire was 65 mass % or more and less than 80 mass %, and the content of the nanowire was 25 mass % or more and less than 45 mass % with respect to the total of the nanowire and the binder. Thus, the sheets had electromagnetic wave absorption of 15 dB or more in the band of 74 to 81 GHz used for a millimeter wave radar even with a small thickness.

The sheet of Comparative Example 3-1, in which the content of the nanowire exceeded 85 mass % with respect to the total of the nanowire and the binder, had low electromagnetic wave absorption due to impedance mismatch.

The sheets of Comparative Examples 3-2 to 3-8, in which a nanowire not containing iron or a nanowire containing too little iron was used, had low absorption performance at the corresponding frequency with a thickness of 100 μm.

### INDUSTRIAL APPLICABILITY

The soft magnetic nanowire of the present invention (in particular, the invention according to the first and second embodiments) is useful for all application (for example, motor cores, electromagnetic valves, various sensors, magnetic field shields, electromagnetic wave absorbers, and the like) in which soft magnetic properties are required.

The electromagnetic wave absorber of the present invention (in particular, the invention according to the third embodiment) is useful for all applications in which electromagnetic wave absorption is required. Such applications include, for example, an antenna unit for wireless communication; and a sensing unit.

1. A soft magnetic nanowire, comprising an iron and a boron and having an average length of 5 μm or more and an iron/boron molar ratio in the nanowire of less than 5, wherein
the iron/boron molar ratio is measured by a SEM-EDS method.

2. The soft magnetic nanowire according to claim 1, wherein
a content of iron is 15 mass % or more with respect to a total content of iron, cobalt, nickel, boron, and silicon, and
a content of boron is 0.1 to 20 mass % with respect to the total content of iron, cobalt, nickel, boron, and silicon.

3. The soft magnetic nanowire according to claim 1, wherein
a content of each of cobalt and nickel is 0.1 mass % or less with respect to an entire amount of the nanowire,
a content of iron in the nanowire is 70 mass % or more with respect to the entire amount of the nanowire,
a content of boron in the nanowire is 3.5 mass % or more with respect to the entire amount of the nanowire, and
a content of the elements other than iron and boron in the nanowire is 25 mass % or less with respect to the entire amount of the nanowire.

4. The soft magnetic nanowire according to claim 3, wherein the content of iron in the nanowire is 85 mass % or more with respect to the entire amount of the nanowire.

5. The soft magnetic nanowire according to claim 4, wherein
the content of boron in the nanowire is 3.5 mass % or more with respect to the entire amount of the nanowire, and
the content of the elements other than iron and boron in the nanowire is 15 mass % or less with respect to the entire amount of the nanowire.

6. The soft magnetic nanowire according to claim 3, wherein
the content of iron in the nanowire is 89 mass % or more with respect to the entire amount of the nanowire, and
the content of boron in the nanowire is 4 mass % or more with respect to the entire amount of the nanowire.

7. The soft magnetic nanowire according to claim 6, wherein the content of the elements other than iron and boron in the nanowire is 8 mass % or less with respect to the entire amount of the nanowire.

8. The soft magnetic nanowire according to claim 1, wherein a total content of cobalt and nickel is 1 to 60 mass % with respect to a total content of iron, cobalt, nickel, boron, and silicon.

9. The soft magnetic nanowire according to claim 8, wherein the soft magnetic nanowire satisfies at least one of Condition (P1) or (P2) shown below:
Condition (P1): a content of iron is 60 mass % or more with respect to the total content of iron, cobalt, nickel, boron, and silicon; or
Condition (P2): a total content of iron and cobalt is 84 mass % or more with respect to the total content of iron, cobalt, nickel, boron, and silicon.

10. The soft magnetic nanowire according to claim 8, wherein the soft magnetic nanowire satisfies at least one of Condition (Q1) or (Q2) shown below:
Condition (Q1): a content of iron is 73.5 mass % or more with respect to the total content of iron, cobalt, nickel, boron, and silicon; or
Condition (Q2): a total content of iron and cobalt is 84 to 90 mass % with respect to the total content of iron, cobalt, nickel, boron, and silicon.

11. The soft magnetic nanowire according to claim 8, wherein
the soft magnetic nanowire further comprises silicon, and
a content of silicon is 0.1 to 1 mass % with respect to the total content of iron, cobalt, nickel, boron, and silicon.

12. The soft magnetic nanowire according to claim 1, wherein the soft magnetic nanowire has:
a saturation magnetization measured using a vibrating-sample magnetometer of 40 emu/g or more,
a coercivity measured using a vibrating-sample magnetometer of less than 500 Oe; and
a relative magnetic permeability measured using a vibrating-sample magnetometer of 5 or more.

13. A method for producing the soft magnetic nanowire according to claim 1, wherein the method comprises performing, in a reaction solvent, a liquid phase reduction reaction in a magnetic field using a metal ion containing an iron ion as a raw material and a reducing agent containing a boron atom.

14. The method for producing the soft magnetic nanowire according to claim 13, wherein the metal ion further contains a cobalt ion and/or a nickel ion.

15. A coating material comprising the soft magnetic nanowire according to claim 1.

16. A laminated body comprising a coating film formed by applying the coating material according to claim 15 onto a substrate.

17. A molded body comprising the soft magnetic nanowire according to claim 1.

18. A sheet comprising the soft magnetic nanowire according to claim 1.

19. An electromagnetic wave shielding material comprising the soft magnetic nanowire according to claim 1.
